(19) United States
(12) Patent Application Publication
(10) Pub. No.: US 2019/0009190 A1
(43) Pub. Date: Jan. 10, 2019

(54) A MICROFLUIDIC DEVICE AND METHODS FOR MANUFACTURING SAME

(71) Applicants: DEAKIN UNIVERSITY, Geelong (AU); UNIVERSITY OF TASMANIA, Sandy Bay (AU)

(72) Inventors: George W. Greene, Brunswick (AU); Brett PAULL, Hobart (AU); Emer DUFFY, Westmeath (IE); Kara SPILSTEAD, Waurn Ponds (AU); Stephen HASWELL, Waurn Ponds (AU)

(21) Appl. No.: 15/753,771

(22) PCT Filed: Aug. 21, 2015
(86) PCT No.: PCT/AU2015/050484

§ 371 Date: Feb. 20, 2018

(51) Int. Cl. B01D 15/20; B01J 20/286; B01J 20/32; B01L 3/00; B81C 1/00; G01N 30/56; G01N 27/447

(52) U.S. Cl. CPC B01D 15/206; B01L 2400/0415; B01J 20/3204; B01J 20/321; B01J 20/3251; B01L 3/502707; B81C 1/00071; G01N 30/56; G01N 27/44752; G01N 27/44791; B01J 2220/84; B01J 2220/86; B01L 2300/0816; B01L 2300/16; B01J 20/286

(57) ABSTRACT

The present invention relates generally to a sample processing device, such as a microfluidic device, comprising a substrate, wherein the substrate comprises a plurality of channels configured to transport a fluid, and wherein the plurality of channels are substantially coated with lubricin, or a functional variant thereof. Also disclosed herein are methods of manufacturing such devices, methods of preventing fouling of a channel in a device using lubricin, or a functional variant thereof and methods of controlling the electrokinetic flow of an analyte through a channel that is substantially coated with lubricin, or a functional variant thereof. Also disclosed herein is chromatographic material for the electrophoretic and/or chromatographic separation of an analyte, wherein the chromatographic material is substantially coated with lubricin, or a functional variant thereof.

### TECHNICAL FIELD

The present invention relates generally to sample processing devices and methods of manufacturing same. More particularly, the present invention relates to microfluidic devices comprising a plurality of channels having a coating that is resistant to biofouling.

### BACKGROUND

Current trends in sample processing using microfluidic and ‘lab-on-a-chip’ technologies promise a new era of highly integrated functionality for unprecedented advancements in medical diagnostics and the study of complex biological and chemical processes. However, despite such promise, the field of microfluidics remains hampered by unwanted adhesion of proteins and other biomaterial to the surfaces of these devices, a process also referred to as biofouling. Microfluidic devices and the like are also prone to biofilm formation, characterised by the unwanted adhesion of cells and other microorganisms, such as bacteria, to its surfaces and the subsequent deposition of extracellular matrix material. Biofouling, including biofilm formation, has an adverse affect the functionality of such devices, for example, by reducing the sensitivity of detection, by altering the electrostatic charge of device surfaces, thereby interfering with electrokinetic transport processes and by the general introduction of extraneous factors that may interfere with sample processing. Biofouling is therefore a significant obstacle to the development of sample processing devices, such as microfluidic devices.

The problem of reducing non-specific protein binding and preventing adhesion of biomaterial that leads to biofilm formation has previously been addressed by modifying the surfaces of microfluidic devices with anti-adhesive and anti-fouling coating materials, such as chemically and physically grafted polyethylene glycol-based polymers; biopolymers such as dextran, hyaluronic acid or heparin, and zwitterionic lipids. While many of these coating technologies are highly effective at blocking adhesion, most possess inherent limitations that significantly limit their wider adoption in commercial microfluidic device technologies. For instance, the chemical grafting of polyethylene glycol (PEG) chains to the substrate surface, a processes commonly referred to as PEGylation, has a number of drawbacks, not least of which is the practical difficulties associated with grafting PEG to substrate surfaces (e.g., polymers). It also often requires complex surface chemistry or the synthesis of a functionalized PEG molecule tailored to give good adhesion to a specific substrate. In addition, many anti-adhesive molecules such as PEG are charge neutral, meaning that the electrostatic charge of the surface modified with the anti-adhesive coating is virtually eliminated. Without an electrostatic charge on the modified surfaces of microfluidic devices, it is almost impossible to control the flow of fluid and the migration of molecules therein by electrokinetic processes. The ability to control the flow of fluid and the migration of biomolecules is an important feature that facilitates the miniaturization and portability of microfluidic devices.

Thus, there is a need for an improved method of reducing nonspecific binding of proteins and other biomaterial to substrate surfaces whilst retaining their ability to support electrokinetic processes, which remain significant obstacles in the development of sample processing devices, especially in the field of microfluidics.

### SUMMARY OF THE INVENTION

In one aspect disclosed herein, there is provided a microfluidic device comprising a substrate, wherein the substrate comprises a plurality of channels configured to transport a fluid, and wherein the plurality of channels are substantially coated with lubricin, or a functional variant thereof.

In another aspect disclosed herein, there is provided a method for manufacturing a microfluidic device comprising: (i) providing a substrate having a plurality of channels configured to transport a fluid, and (ii) applying to the plurality of channels a coating solution comprising lubricin, or a functional variant thereof, under conditions to allow the lubricin or functional variant thereof to substantially coat the plurality of channels.

In another aspect disclosed herein, there is provided a method of preventing fouling of a channel in a microfluidic device, the method comprising coating the channel with lubricin, or a functional variant thereof.

In another aspect disclosed herein, there is provided a method of controlling the electrokinetic flow of an analyte through a channel of a microfluidic device, the method comprising passing a fluid comprising the analyte through the channel under the influence of an electric field applied between a first position and a second position along the channel, wherein the channel is substantially coated with lubricin, or a functional variant thereof.

In another aspect disclosed herein, there is provided a chromatographic material for the electrophoretic separation of an analyte, wherein the chromatographic material is substantially coated with lubricin, or a functional variant thereof.

In another aspect disclosed herein, there is provided a chromatographic material for the chromatographic separation of an analyte, wherein the chromatographic material is substantially coated with lubricin, or a functional variant thereof.

### BRIEF DESCRIPTION OF THE FIGURES

FIG. 1(a) shows a schematic illustration of the adsorbed conformational structure of lubricin (LUB) protein layers on a gold substrate. The LUB protein has been show to self-assemble in to a telechelic polymer brush with a thickness of approximately 100 nm (almost exactly ½ the molecules contour length). The ‘minimum area’ is the average area of the surface occupied by a single LUB molecule and was calculated from the average Sauerbrey mass (which is an underestimation of the true mass) of LUB adsorbed onto gold at pH 7.4 from 15 separate QCM experiments. This minimum area is slightly less than, but still in good agreement with the grafting density calculated for lubricin brushes reported in Ref [24]. FIG. 1(b) is a schematic illustration of the LUB protein, showing the central mucin domain and the two end domains; that szomatomedin-B (SMB)-like domain at the N-terminus and the Homeopaxin (HPX)-like domain at the C-terminus.

FIG. 2 shows an SDS-PAGE gel of the purified LUB (lane #1) and an unused lane (lane #2). The LUB appears as a band at approximately 260 kDa while a much weaker band is observed at approximately 180 kDa. The band at approximately 100 kDa is a gel artifact that was present in all the lanes, even the ones that were not loaded with sample. The purity of the LUB (as a fraction of total protein content) was assessed at ˜87%.

FIG. 3 shows a schematic representation ((a); not to scale) and actual experimental data (b) showing the measured change in frequency, ΔF, and dissipation, ΔD, in of a typical Quartz Crystal Microbalance (QCM) experiment. The QCM experiment shown in (b) was run in PBS buffer at pH 7 and shows the adsorption of lubricin onto a gold sensor surface (i.e., stage (1) to (3)) followed by the measurement of the non-specific adsorption of IgG to the LUB layer (i.e., stage (3) to (5)). Note that the jagged appearance of the ΔF, and AD curves in (b) during stage (2) is due to the stopping and restarting of the flow of the LUB solution during the experiment which was done to minimize waste and the amount of LUB solution necessary to achieve saturated coverage of the sensor surface. Details of the measurements are described in the Examples section herein (“Quartz Crystal Microbalance Measurements”).

FIG. 4 shows AFM height images and line (surface contour) profiles for surfaces with various coatings used in these experiments. The vertical scale of the images is 0-2.4 nm, and in each case the scale bar represents 500 nm. The root-mean-square roughness values (R_{RMS}) were calculated over a 4 μm² area. Line profiles were taken vertically through the centre of each image and have been vertically offset for clarity of presentation.

FIG. 5 shows plots of the mass density of non-specifically adsorbed IgG (a and b) and bovine serum albumin (BSA; c and d) proteins as a function of the PBS solution pH measured on uncoated and coated gold surfaces. (a) the non-specific binding of IgG from a 0.25 mg/ml solution as a function of the PBS pH for uncoated gold and LUB, PEG (two different Molecular weights), and pig gastric mucin coated gold surfaces. (b) a higher resolution plot of the same data shown in (a) for the PEG and LUB coated surfaces. (c) the non-specific binding of BSA from a 2 mg/ml solution as a function of the PBS pH for uncoated gold and for LUB, PEG (at two different molecular weights; 356 and 2,000), and pig gastric mucin coated gold surfaces. (d) a higher resolution plot of the same data shown in (a) for the PEG and LUB coated surfaces.

FIG. 6 shows the mass density of non-specifically adsorbed material from a 50% dilution in PBS (pH 7.4) of human blood plasma on uncoated and LUB and PEG (two different molecular weights) coated surfaces.

FIG. 7(a) is a plot showing the mass density of adsorbed non-specifically adsorbed IgG and LUB protein onto unmodified and variously chemically modified gold sensor surfaces. The blue bars show the mass density of adsorbed IgG onto the bare modified and unmodified surfaces. The red bars show the mass density of LUB adsorbed to the modified and unmodified surfaces. The light blue bars show the mass density of IgG adsorbed to the previously adsorbed LUB layers (i.e., the red bars) on the modified and unmodified surface. All measurements were performed using PBS buffer at pH 7.4. FIG. 7(b) is a plot showing the change in dissipation ΔD vs. the change in frequency, ΔF, from representative lubricin adsorption data (i.e., collected at stages (2) and (3) in FIGS. 2a-b) that was used to calculate the LUB adsorbed mass to the different substrates shown in (a).

FIG. 8 shows a plot of the mass density of adsorbed IgG protein as a function of the adsorbed mass density of LUB protein. For clarity, the adsorbed mass density of LUB has been normalized to give the percent of saturated mass density which is shown on a second x-axis.

FIG. 9 shows a plot of the adsorbed mass density of BSA protein as a function of the aging time at ambient temperatures, first under vacuum conditions and then under ambient atmospheric conditions. Note that all the data points are similar to the range of values reported in FIG. 3d for the non-specific adsorption of BSA on freshly deposited LUB at pH 7.4.

FIG. 10 is a schematic representation of a hybrid glass/polydimethyl siloxane (PDMS) microfluidic device having a ‘cross-channel’ chip configuration, comprising four reservoirs: a ‘Loading Channel Inlet,’ a ‘Loading Channel Outlet,’ a ‘Buffer Channel,’ and a ‘Detector Channel’. The region of detection (Detector) is also shown.

FIGS. 11a and 11a′ show the EOF velocities within LUB-coated silica and PTFE capillaries, respectively, under an applied electric field of 10 kV (E=357 V/cm and E=297 V/cm respectively) in various 15 mM background electrolyte buffers having a range of pH values (5-9 for LUB-coated silica capillaries and 6-12 for LUB-coated PTFE capillaries). FIGS. 11b and b′ show the relationship between the μ_{EOF} and run buffer pH for LUB-coated silica and PTFE capillaries, respectively. FIGS. 11c and c′ show the relationship between the zeta-potential (ζ) and the run buffer pH for LUB-coated silica and PTFE capillaries, respectively.

FIG. 12 shows the consistency and uniformity of the electroosmotic mobility (i.e. electrohydrodynamic properties) between different LUB coatings. Each coating was applied to the same silica capillary. In between coatings, the LUB layer was stripped away by rinsing the capillary with a 2M NaOH before the coating was reapplied.

FIG. 13a shows the migration times obtained for the EOF of a clean BGE (pH 7.25; 10 mM MOPS) and single and mixed solutions of BSA and IgG in a LUB-coated PTFE capillary. FIGS. 13b and 13c show the EOF and migration times for BSA and IgG over a series of 11 consecutively run electrokinetic separations in a LUB-coated PTFE capillary.

FIG. 14 are fluorescent micrographs showing the fluorescence over different exposure times (a=2s; b=2s, c=20 ms, d=200 ms) of FITC-labelled IgG in 10 mM MOPS buffer (pH 7.25) that was injected into the uncoated (a and c) or LUB-coated (b and d) PDMS microfluidic cross-channel chip as shown in FIG. 10.

FIG. 15 shows the electroosmotic injection (FIGS. 6a-d) and fluorescent detection (FIG. 6e) of a 0.5 mg/ml solution of FITC-labelled IgG that was injected into the PDMS cross-channel chip as shown in FIG. 10.

FIG. 16 shows the cyclic voltammagrams (CV) of the oxidation and reduction of K₃[Fe(CN)₆] in phosphate buffered saline solution measured using an uncoated and LUB-coated glassy carbon electrode. The CVs show that the LUB coating is electroactive, electrochemically stable, does not significantly reduce the electrochemical reaction kinetics, and does not affect the reversibility of the electrochemical reaction.

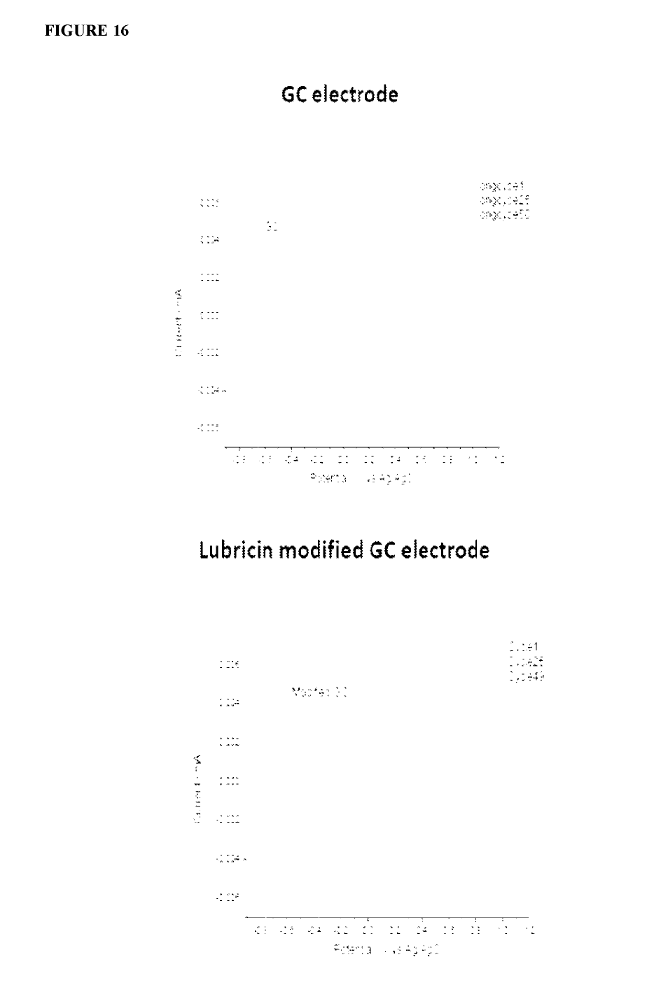

### DETAILED DESCRIPTION

The terminology used herein is for the purpose of describing particular embodiments only and is not intended to be limiting. Unless defined otherwise, all technical and scientific terms used herein have the same meanings as commonly understood by one of ordinary skill in the art to which the present disclosure belongs. Any materials and methods similar or equivalent to those described herein can be used to practice the present invention. Practitioners may refer to common textbooks and other reference material for definitions and terms of the art and other methods known to the person skilled in the art.

Throughout this specification, unless the context requires otherwise, the word “comprise”, or variations such as “comprises” or “comprising”, will be understood to imply the inclusion of a stated element or integer or group of elements or integers but not the exclusion of any other element or integer or group of elements or integers.

By “consisting of” is meant including, and limited to, whatever follows the phrase “consisting of”. Thus, the phrase “consisting of” indicates that the listed elements are required or mandatory, and that no other elements may be present. By “consisting essentially of” is meant including any elements listed after the phrase, and limited to other elements that do not interfere with or contribute to the activity or action specified in the disclosure for the listed elements. Thus, the phrase “consisting essentially of” indicates that the listed elements are required or mandatory, but that other elements are optional and may or may not be present depending upon whether or not they affect the activity or action of the listed elements.

As used herein the singular forms “a”, “an” and “the” include plural aspects unless the context clearly dictates otherwise. Thus, for example, reference to “a channel” includes a single channel, as well as two or more channels; reference to “a molecule” includes one molecule, as well as two or more molecules; and so forth.

The present disclosure is predicated, at least in part, on the inventors' surprising findings that lubricin will attach to almost any material surface to provide a surface that is resistant to nonspecific binding of proteins and other biomaterials, and that this anti-adhesive property of lubricin remains stable over time and resistant to changes in conditions such as pH and temperature. The anti-adhesive property of lubricin coatings was also found to be as effective as, or better than, self-assembled monolayers of polyethylene glycol (PEG).

The present disclosure is also predicated, in part, on the inventors' surprising finding that lubricin-coated surfaces possess an electrohydrodynamic property that makes them useful for supporting the mobility of analytes by electrokinetic processes and that this property is largely unaffected by changes in pH and analyte concentration. Combined with its ability to readily self-assemble to form dense, highly stable telechelic polymer brush layers on virtually any substrate surface, and its innate biocompatibility, these findings demonstrate that lubricin is a simple, versatile, highly stable, and highly effective coating that can be used to control unwanted adhesion and biofouling of almost any type of substrate surface and is particularly useful as an anti-adhesive coating in microfluidic devices where fluid flow is controlled, at least in part, by electrokinetic processes.

Thus, in one aspect, there is provided a microfluidic device comprising a substrate, wherein the substrate comprises a plurality of channels configured to transport a fluid, and wherein the plurality of channels are substantially coated with lubricin, or a functional variant thereof.

Whilst the dual anti-adhesive and electrohydrodynamic properties of lubricin makes it particularly useful as an anti-adhesive coating for microfluidic devices, it is to be understood that these properties also makes lubricin useful as an anti-adhesive coating for any sample processing device or surface thereof that is prone to biofouling. Thus, in another aspect disclosed herein, there is provided a sample processing device comprising a substrate, wherein the substrate comprises a surface configured to transport a fluid, and wherein the surface is substantially coated with lubricin, or a functional variant thereof.

### Lubricin

Lubricin (LUB), also known as Proteoglycan 4 (PRG4), is a highly conserved, mucin-like glycoprotein, whose primary function in vivo appears to be as an articular boundary lubricant necessary for maintaining articular joint health. First isolated in the 1980's, lubricin has since been shown to reduce friction between pressurized and rubbing articular surfaces. As outlined in a review by Jay and Waller in 2014 (“The biology of Lubricin: Near frictionless joint motion”; Matrix Biology, 39:17-24), lubricin is a major contributor to joint longevity, with independent studies using recombinant forms also highlighting the role of intra-articular lubricin administration as a method of treating and preventing arthritis.

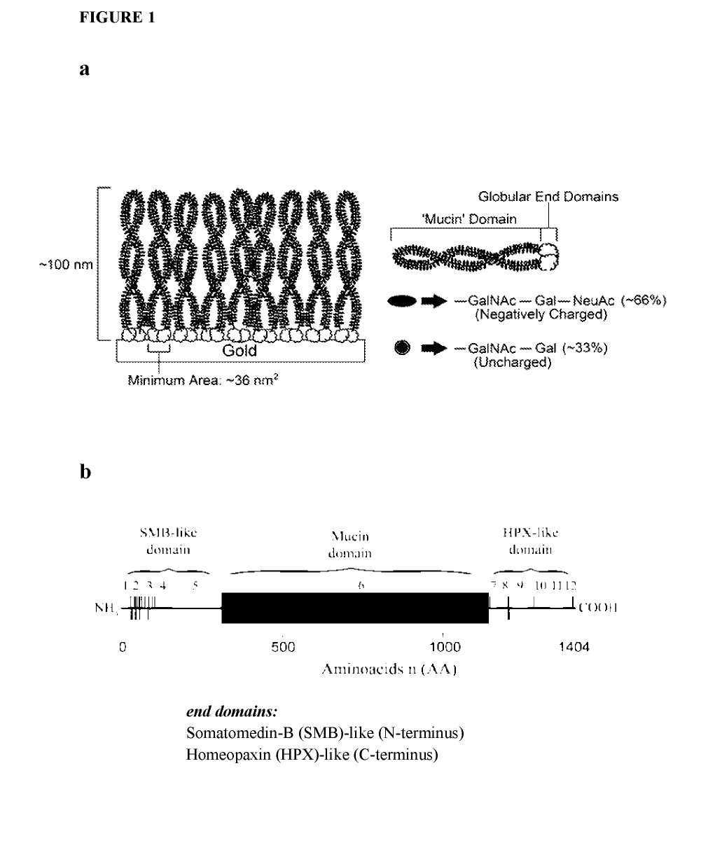

Lubricin is a structureless, flexible molecule with a fully extended contour length of l_{c}≈200 nm and a diameter of a few nanometers (see FIG. 1). Its molecular weight (about 280 kDa) is high compared to the number of amino acids in the sequence (around 800). This is primarily due to the heavy glycosylation of the central portion of the molecule, also referred to as the “mucin domain” (see FIG. 1). The mucin domain of lubricin comprises short polar (-GalNAc-Gal) and negatively charged (-GalNAc-Gal-NeuAc) sugar groups which are O-linked to threonine residues. The glycosylation is almost complete and almost 67% of the sugar groups are capped by negatively charged sialic acid (i.e., -NeuAc). The central mucin domain comprises a very high density of negative charge (with essentially no positive charges) and is primarily responsible for lubricin's lubrication properties. The end domains of the native lubricin molecule are not glycosylated and contain two subdomains that are similar to somatomedin-B and homeopexin. These end domains are extremely sticky and are able to adhere to almost all types of material surfaces. The end domains have also been shown to associate with each other, allowing the central mucin domain to form molecular loops, dimers, trimers, and tetramers where the loops, joined through associated end domains, adopt ‘figure eight’ and larger, loosely twisted aggregate structures. Lubricin is amphiadhesive and the self-associating sticky ends allow for adsorption onto almost any surface or indeed other molecules, such as hyaluronic acid. Several naturally-occurring splice variants of lubricin have also been reported.

When native lubricin molecules attach to a material surface, primarily via their terminal globular end domains, they typically self-assemble into a dense, telechelic brush layer, where the self-association of the molecule's globular end domains serve to enhance how densely the lubricin is able the adsorb onto surfaces, and thus how extended the brush layer becomes. The telechelic brush architecture adopted by the adsorbed lubricin molecules hides the underlying substrate, while exposing the larger, heavily glycosylated mucin domain. A schematic and details of the adsorbed lubricin brush layer architecture is shown in FIG. 1.

The amphiadhesive nature of the lubricin molecule and its ability to self-assemble into a telechelic brush structure makes lubricin an attractive candidate for use as an anti-adhesive and anti-fouling coating in such applications as microfluidics and biosensors, where controlling the adhesion of proteins and other biomaterials is essential and persistently problematic. The present inventors have also surprisingly found that the anti-adhesive property of surface-adsorbed lubricin molecules is largely resistant to changes in pH and temperature, as well as remaining stable over time.

Lubricin can be derived from any natural source or it can be recombinantly produced. In an embodiment disclosed herein, lubricin is derived from one or more natural sources. Suitable natural sources of lubricin will be known to persons skilled in the art, an illustrative example of which is synovial fluid (e.g., bovine synovial fluid, human synovial fluid). Suitable methods of extracting lubricin from a natural source will also be familiar to persons skilled in the art. An illustrative example is described herein, as well as by Greene et al. (2015, Biomaterials 53; 127-136).

In humans, lubricin is encoded by the megakaryocyte stimulating factor (MSF) gene, also known as PGR4 (see, for example, NCBI accession number AK131434; U70136). The gene encoding naturally-occurring full length lubricin typically comprises 12 exons encoding 1,404 amino acids with multiple polypeptide sequence homologies to vitronectin. Centrally-located exon 6, which encodes the repeat rich, 0-glycosylated mucin domain, encodes 940 residues.

In its natural form, lubricin comprises multiple repeats of the KETAPTT motif. The amino acid sequence of the lubricin backbone may differ depending on alternative splicing of exons of the human MSF gene. However, as lubricin serves a primarily mechanical role, its tertiary structure is somewhat less critical than other proteins whose function depends on their stereochemistry (e.g., immunoglobulins). This was evidenced by previous independent studies which showed that a recombinant form of lubricin missing 474 amino acids from its central mucin domain retained much of its lubricating function. As noted elsewhere herein, native lubricin has been shown to exist as a monomer, a dimer and as a multimer via disulfide bonds through the conserved cysteine-rich domains at both N- and C-termini.

In another embodiment, the lubricin is a recombinant lubricin molecule. Suitable methods for producing recombinant lubricin will be familiar to persons skilled in the art. For example, a nucleic acid molecule comprising a nucleic acid sequence encoding lubricin, or a functional variant thereof, can be transfecting into a suitable host cell capable of expressing said nucleic acid sequence, incubating said host cell under conditions suitable for the expression of said nucleic acid sequence, and recovering the recombinant protein or variant. Suitable methods for preparing a nucleic acid molecule encoding lubricin or a functional variant thereof will also be familiar to persons skilled in the art, for example, based on knowledge of the nucleic acid sequence, possibly including optimizing codons based on the nature of the host cell (e.g. microorganism) to be used for expressing and/or secreting the recombinant protein. Suitable host cells will also be known to persons skilled in the art, illustrative examples of which include prokaryotic cells (e.g., E. coli) and eukaryotic cells (e.g., P. pastoris). Another illustrative example of a suitable host cell is a Chinese hamster ovary cell (CHO), Reference is made to “Short Protocols in Molecular Biology, 5th Edition, 2 Volume Set: A Compendium of Methods from Current Protocols in Molecular Biology” (by Frederick M. Ausubel (author, editor), Roger Brent (editor), Robert E. Kingston (editor), David D. Moore (editor), J. G. Seidman (editor), John A. Smith (editor), Kevin Struhl (editor), J Wiley & Sons, London). Suitable methods for codon optimisation will also be known to persons skilled in the art, such as using the “Reverse Translation” option of Gene Design tool located in “Software Tools” on the John Hopkins University Build a Genome website.

As used herein, the terms “encode,” “encoding” and the like refer to the capacity of a nucleic acid to provide for another nucleic acid or a protein. For example, a nucleic acid sequence is said to “encode” a protein if it can be transcribed and/or translated, typically in a host cell, to produce the protein or if it can be processed into a form that can be transcribed and/or translated to produce the protein. Such a nucleic acid sequence may include a coding sequence or both a coding sequence and a non-coding sequence. Thus, the terms “encode,” “encoding” and the like include an RNA product resulting from transcription of a DNA molecule, a protein resulting from translation of an RNA molecule, a protein resulting from transcription of a DNA molecule to form an RNA product and the subsequent translation of the RNA product, or a protein resulting from transcription of a DNA molecule to provide an RNA product, processing of the RNA product to provide a processed RNA product (e.g., mRNA) and the subsequent translation of the processed RNA product.

An illustrative example of a method for producing recombinant lubricin, or a functional variant thereof, is described by Flannery et al. (2009, Arthritis & Rheumatism, 60(3):840-847) and in U.S. Pat. No. 7,642,236.

In an embodiment disclosed herein, the recombinant lubricin is a full-length recombinant form of human lubricin. In an embodiment, the recombinant form of human lubricin has an apparent molecular weight of 450-600 kDa, with polydisperse multimers frequently measuring at 2,000 kDa or more, all as estimated by comparison to molecular weight standards on SDS tris-acetate 3-8% polyacrylamide gels.

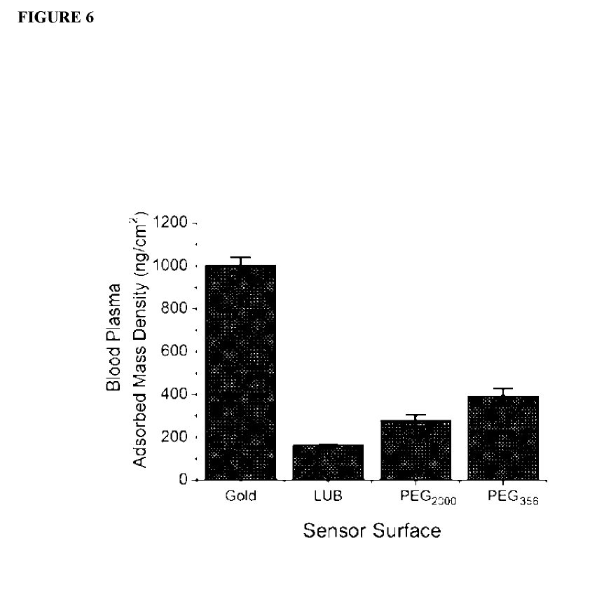

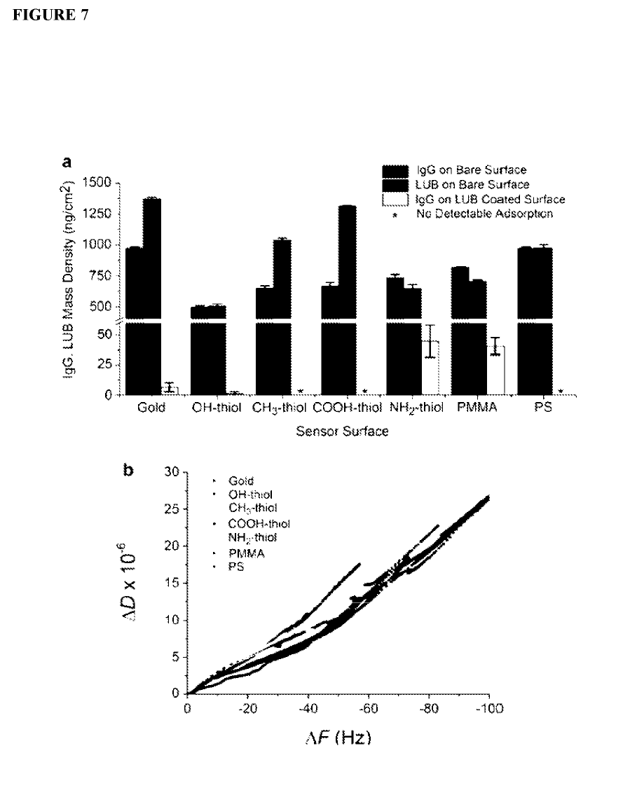

Further illustrative examples of suitable recombinant lubricin molecules that may be used in accordance with the present invention, and methods for their production, are described in U.S. Pat. Nos. 6,433,142, 6,743,774, 6,960,562, 7,030,223 and 7,361,738, each of which is incorporated herein by reference in their entirety. In an embodiment, the lubricin is a full length, glycosylated, recombinant human lubricin molecule having the amino acid sequence shown in FIG. 6 of WO 2015/081121, encoded by the nucleic acid sequence shown in FIG. 7 of WO 2015/081121, which is incorporated herein by reference in its entirety.

In an embodiment disclosed herein, the lubricin is the natural full-length molecule, as previously described by Swann et al. (1985, Biochem J. 225(1):195-201). As used herein, the terms “native”, “natural” and “naturally-occurring” are used interchangeably to refer to the full-length lubricin molecule as normally found in nature, as is described, for example, by Swann et al. (1985, Biochem J. 225(1):195-201). Conversely, the terms “non-native” and “non-naturally-occurring” are used interchangeably herein to refer to a lubricin molecule having an amino acid sequence that is different to the amino acid sequence of a native lubricin molecule.

In an embodiment, lubricin comprises, consists of, or consists essentially of, the amino acid sequence shown in NCBI accession number AK131434 (U70136), or an amino acid sequence having at least 70% sequence identity or similarity thereto. In another embodiment, lubricin comprise or consists of, or consists essentially of the amino acid sequence of SEQ ID NO:7 as described in U.S. Pat. No. 7,642,236, or an amino acid sequence having at least 70% sequence identity or similarity thereto. In another embodiment, lubricin comprise or consists of, or consists essentially of the amino acid sequence as shown in FIG. 6 of WO 2015/081121, or an amino acid sequence having at least 70% sequence identity or similarity thereto.

### Functional Variants

The term “functional variant”, as used herein, includes a molecule that varies in amino acid sequence and/or structure from the native (i.e., naturally-occurring) lubricin molecule, yet retains at least some of the anti-adhesive properties that are attributed to the native lubricin molecule, as described elsewhere herein (e.g., the ability to inhibit non-specific protein binding to a coated surface, the ability to inhibit attachment and subsequent proliferation of bacteria to a coated surface, etc.). Illustrative examples of functional variants include molecules comprising an amino acid sequence having at least 70% sequence identity or similarity to the native lubricin protein (e.g., NCBI accession number AK131434 (U70136)).

Reference to “at least 70%” includes 70, 71, 72, 73, 74, 75, 76, 77, 78, 79, 80, 81, 82, 83, 84, 85, 86, 87, 88, 89, 90, 91, 92, 93, 94, 95, 96, 97, 98 or 99% sequence identity or similarity, for example, after optimal alignment or best fit analysis. The terms “identity”, “similarity”, “sequence identity”, “sequence similarity”, “homology”, “sequence homology” and the like, as used herein, mean that at any particular amino acid residue position in an aligned sequence, the amino acid residue is identical between the aligned sequences. The term “similarity” or “sequence similarity” as used herein, indicates that, at any particular position in the aligned sequences, the amino acid residue is of a similar type between the sequences. For example, leucine may be substituted for an isoleucine or valine residue. This may be referred to as conservative substitution. In an embodiment, the amino acid sequences may be modified by way of conservative substitution of any of the amino acid residues contained therein, such that the modification has no effect on the binding specificity or functional activity of the modified polypeptide when compared to the unmodified polypeptide. The phrase “conservative amino acid substitution” is to be understood as referring to changing the amino acid identity at a given position with an amino acid of approximately equivalent size, charge and/or polarity. Examples of natural conservative substitutions of amino acids include the following 8 substitution groups (designated by the conventional one-letter code): (1) M, I, L, V; (2) F, Y, W; (3) K, R, (4) A, G; (5) S, T; (6) Q, N; (7) E, D; and (8) C, S. The terms “amino acid” or “amino acid residue”, as used herein, encompass both natural and unnatural or synthetic amino acids, including both the D- or L-forms, and amino acid analogs. An amino acid also includes an “amino acid analog”, which is to be understood as a non-naturally occurring amino acid differing from its corresponding naturally occurring amino acid at one or more atoms. For example, an amino acid analog of cysteine may be homocysteine.

In some embodiments, sequence identity with respect to a polypeptide relates to the percentage of amino acid residues in the candidate sequence which are identical with the residues of the corresponding polypeptide after aligning the sequences and introducing gaps, if necessary, to achieve the maximum percentage homology, and not considering any conservative substitutions as part of the sequence identity. Neither N- or C-terminal extensions, nor insertions shall be construed as reducing sequence identity or homology. Methods and computer programs for performing an alignment of two or more amino acid sequences and determining their sequence identity or homology are well known to persons skilled in the art. For example, the percentage of identity or similarity of two amino acid sequences can be readily calculated using algorithms, for example, BLAST, FASTA, or the Smith-Waterman algorithm.

In some embodiments, sequence identity with respect to a polynucleotide relates to the percentage of nucleotides in the candidate sequence which are identical with the nucleotides of the corresponding polynucleotide after aligning the sequences and introducing gaps, if necessary, to achieve the maximum percentage homology, and not considering any conservative substitutions as part of the sequence identity. Methods and computer programs for performing an alignment of two or more protein or nucleic acid sequences and determining their sequence identity or homology are well known to persons skilled in the art.

Techniques for determining an amino acid sequence “similarity” are well known to persons skilled in the art. In general, “similarity” means an exact amino acid to amino acid comparison of two or more proteins or at the appropriate place, where amino acids are identical or possess similar chemical and/or physical properties such as charge or hydrophobicity. A so-termed “percent similarity” then can be determined between the compared polypeptide sequences. Techniques for determining nucleic acid and amino acid sequence identity also are well known in the art and include determining the nucleotide sequence of the mRNA for that gene (usually via a cDNA intermediate) and determining the amino acid sequence encoded thereby, and comparing this to a second amino acid sequence. In general, “identity” refers to an exact nucleotide to nucleotide or amino acid to amino acid correspondence of two nucleic acid or amino acid sequences, respectively.

Two or more polynucleotide sequences can also be compared by determining their “percent identity”. Two or more amino acid sequences likewise can be compared by determining their “percent identity”. The percent identity of two sequences, whether nucleic acid or peptide sequences, may be described as the number of exact matches between two aligned sequences divided by the length of the shorter sequence and multiplied by 100. An approximate alignment for nucleic acid sequences is provided by the local homology algorithm of Smith and Waterman, Advances in Applied Mathematics 2:482-489 (1981). This algorithm can be extended to use with peptide sequences using the scoring matrix developed by Dayhoff, Atlas of Protein Sequences and Structure, M. O. Dayhoff ed., 5 suppl. 3:353-358, National Biomedical Research Foundation, Washington, D.C., USA, and normalized by Gribskov, Nucl. Acids Res. 14(6):6745-6763 (1986). Suitable programs for calculating the percent identity or similarity between sequences are generally known in the art.

An illustrative example for determining nucleic acid sequence identity uses a subject nucleic acid sequence to search on a nucleic acid sequence database, such as the GenBank database (accessible at http://www.ncbi.nln.nih.gov/blast/), using the program BLASTN version 2.1 (based on Altschul et al. (1997) Nucleic Acids Research 25:3389-3402). This program can be used in the ungapped mode. Default filtering is used to remove sequence homologies due to regions of low complexity. The default parameters of BLASTN can be used. An illustrative example for determining amino acid sequence identity, an amino acid sequence is used to search a protein sequence database, such as the GenBank database (accessible at web site http://www.ncbi.nln.nih.gov/blast/), using the BLASTP program. The program can be used in the ungapped mode. Default filtering is used to remove sequence homologies due to regions of low complexity. The default parameters of BLASTP are utilized. Filtering for sequences of low complexity may use the SEG program.

Optimal alignment of sequences for aligning a comparison window may be conducted by computerized implementations of algorithms (GAP, BESTFIT, FASTA, and TFASTA in the Wisconsin Genetics Software Package Release 7.0, Genetics Computer Group, 575 Science Drive Madison, Wis., USA) or by inspection and the best alignment (i.e., resulting in the highest percentage homology over the comparison window) generated by any of the various methods selected. Reference also may be made to the BLAST family of programs as for example disclosed by Altschul et al., 1997, Nucl. Acids Res.25:3389. A detailed discussion of sequence analysis can be found in Unit 19.3 of Ausubel et al., “Current Protocols in Molecular Biology”, John Wiley & Sons Inc, 1994-1998, Chapter 15.

Functional variants also encompass isolated or purified native or recombinant lubricin proteins, homologs, functional fragments, isoforms, and/or mutants thereof. In some embodiments, a functional variant will comprise the sequence encoded by exon 6 of the MSF (PRG4) gene, or homologs or truncated versions thereof, for example, versions with fewer repeats of the central mucin-like KETAPTT-repeat motifs, together with 0-linked glycosylation. In other embodiments, a functional variant will comprise portions of the sequences encoded by exons 1-5 and 7-12 of the MSF gene. In other embodiments, the functional variant will have an average molar mass of between 50 kDa and 500 kDa, preferably between 224 to 467 kD, more preferably between 220 kDa to about 280 kDa.

Functional variants also include naturally-occurring variants (or isoforms) derived from human or other species, such as bovine.

Functional variants also encompass fragments of the native lubricin molecule. Suitable examples of functional fragments include fragments of lubricin that consist of, consist essentially of or comprise an amino acid sequence having at least 50% sequence identity or similarity to native lubricin. Without being bound by theory or by a particular mode of application, the anti-adhesive property of lubricin is attributed, at least in part, to its centrally-located mucin domain. Thus, in an embodiment disclosed herein, the functional variant is a fragment of lubricin comprising at least a portion of the central mucin domain. It is to be understood that such fragments will typically comprise at least a portion of the mucin domain that would allow the fragment to retain at least some of the anti-adhesive property of the native lubricin molecule; that is, resistance against nonspecific protein binding and adherence of other biomaterial (e.g., cells, including bacteria) to a surface coated therewith. Suitable methods for determining whether or not a fragment of lubricin retains sufficient anti-adhesive properties when coated onto a surface will be known to persons skilled in the art, illustrative examples of which are described elsewhere herein. In an embodiment disclosed herein, the functional variant comprises, consists or consists essentially of a fragment of lubricin's central mucin domain. In an embodiment, the fragment comprises, consists or consists essentially of at least 50% of the central mucin domain. By “at least 50%” is meant at least 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98 or 99% of the central mucin domain of the native lubricin molecule. In an embodiment, the functional variant comprises, consists or consists essentially of a truncated lubricin molecule that retains enough of the central mucin domain so as to allow the formation of a telechelic brush layer, similar to that seen with coatings of native lubricin.

As described elsewhere herein, the inventors have shown that lubricin attaches to almost any material surface, at least in part, by its sticky end domains; that is, the somatomedin-B-like and homeopexin-like end domains of native lubricin. In some embodiments, only one of the two end domains will be sufficient to allow the molecule to attach to a surface. Thus, in an embodiment disclosed herein, the functional variant is a fragment of native lubricin comprising, consisting or consisting essentially of at least a portion of the central mucin domain, as herein described, in combination with the somatomedin-B-like end domain or the homeopexin-like end domain of native lubricin. For example, in one embodiment, the fragment comprises, consists or consists essentially of at least a portion of the central mucin domain and the somatomedin-B-like end domain of native lubricin, but not the homeopexin-like end domain of native lubricin. In another embodiment, the fragment comprises, consists or consists essentially of at least a portion of the central mucin domain and the homeopexin-like end domain of native lubricin, but not the somatomedin-B-like end domain of native lubricin. The degree of attachment of the functional variant to a surface can be readily determined by persons skilled in the art using known methods, including those described elsewhere herein.

The inventors have also shown that lubricin can attach to a substrate surface by its central mucin domain (e.g., by electrostatic interaction) and, hence, independently of its somatomedin-B-like and/or homeopexin-like end domains. Thus, in another embodiment disclosed herein, the functional variant comprises, consists or consists essentially of at least a portion of the central mucin domain, as herein described, but does not comprise either the somatomedin-B-like end domain or the homeopexin-like end domain.

In another embodiment disclosed herein, the functional variant comprises, consists or consists essentially of a truncated mucin domain, as herein described, but retains either or both of the somatomedin-B-like and homeopexin-like end domains of native lubricin. For example, in one embodiment, the functional variant comprises, consists or consists essentially of a truncated mucin domain and the somatomedin-B-like end domain of native lubricin, but does not comprise the homeopexin-like end domain of native lubricin. In another embodiment, the functional variant comprises, consists or consists essentially of a truncated mucin domain and the homeopexin-like end domain of native lubricin, but does not comprise the somatomedin-B-like end domain of native lubricin. In another embodiment, the functional variant comprises, consists or consists essentially of a truncated mucin domain and both the homeopexin-like end domain of native lubricin and the somatomedin-B-like end domain.

As the present inventors have shown, lubricin can attach to almost any surface (e.g., hydrophobic, anionic, polar, uncharged, cationic, hydrophilic, etc.), predominantly through its adhesive end domains, but also via an interaction between the substrate surface and the central mucin domain of a lubricin molecule. This allows recombinant or native lubricin, or functional variants thereof, to be easily used as a coating for almost any surface, without further modification. Therefore, whilst unnecessary, it will be understood that the lubricin molecule, or functional variant thereof, may be modified to incorporate one or more functional groups or binding moieties to facilitate the attachment of the lubricin molecule to a compatible (e.g., functionalized) substrate surface. Such modifications can be made in lieu of the somatomedin-B-like and/or homeopexin-like end domains of native lubricin or in addition thereto.

### Microfluidic Devices

The term “microfluidic device”, as used herein, broadly encompasses a substrate having one or more channels or flow paths that are configured to transport or carry a fluid therein. Common fluids used in microfluidic devices include whole blood samples, bacterial cell suspensions, protein or antibody solutions and various buffers. Microfluidic devices can be used to obtain a variety of measurements including molecular diffusion coefficients, fluid viscosity, pH, chemical binding coefficients and enzyme reaction kinetics. Other applications for microfluidic devices include capillary electrophoresis, isoelectric focusing, immunoassays, flow cytometry, sample injection of proteins for analysis via mass spectrometry, PCR amplification of nucleic acid molecules, DNA analysis, cell manipulation, cell separation, cell patterning, analyte separation and sorting and chemical gradient formation.

A microfluidic device typically refers to a device that enables the processing and/or analysis of a fluid on a very small scale, typically measured in volumes such as milliliter (mL), microliter (4), nanoliter (nL), picoliter (pL), or femtoliter (fL) and/or by physical scale such as millimeter (mm), micrometer (μm) (also referred to as “micron”), nanometer (nm), etc. Microfluidic devices typically comprise a plurality of channels, also referred to interchangeably as micro-channels, capillaries, tubes and conduits, that form an array or a network of flow paths on a substrate, each channel configured to transport a fluid, typically in a controlled manner. The channels of microfluidic devices can be of uniform cross-section, typically in the mm, μm or nm scale.

Historically, microfluidic devices comprised a relatively simple array of channels that were used to perform simple functions, such as electrophoresis. In recent years, microfluidic devices have rapidly evolved towards greater functionality and integration. Microfluidic devices can now be fabricated to perform many different functions, such as mixing, splitting/separating, sorting and heating, alone or in combination, and can therefore be configured to carry out more complex chemical, biochemical and biological processes and reactions. Such processes and reactions are typically limited only by design (e.g., by the number or conformation of channels, reaction sites, valves, pumps, sensors, heaters, etc). Illustrative examples include DNA amplification, protein fractionation and/or purification, analyte detection and cell sorting. Among other advantages, microfluidic devices significantly reduce the amount of sample and reagents required, shorten the response time of reactions, and decrease the amount of biohazard waste for disposal.

The use of microfluidic devices to conduct biomedical research and create clinically useful technologies has a number of advantages. First, because the volume of fluids within these channels is very small, usually several nanoliters, the amount of reagents and analytes used is quite small. This is especially significant for expensive reagents. The fabrications techniques used to construct microfluidic devices are relatively inexpensive and are very amenable both to highly elaborate, multiplexed devices and also to mass production. Microfluidic technologies enable the fabrication of highly integrated devices for performing several different functions on the same substrate, allowing integrated, portable clinical diagnostic devices for home and bedside use.

Persons skilled in the art will recognise that an almost unlimited number of microfluidic devices can be manufactured, each differing by design; for example, by the number and/or layout of channels, reaction sites, valves, pumps, sensors, heaters, etc. The fabrication of the microfluidic device will invariably depend on its intended use. For example, where the microfluidic device is to be used only to purify one or more proteins from a biological fluid (e.g., chromatographic applications), the device may not require a sensor or detector. Conversely, where the microfluidic device is to be used to detect a nucleic acid molecule of interest present a biological fluid, the device may comprise an RNA or DNA isolation chamber, a nucleic acid amplification chamber and a sensor/detector. An illustrative example of such a device include those described in WO 2010/041088 and WO 2012/038462, the contents of which are incorporated herein by reference in their entirety.

In an embodiment, the microfluidic device comprises one or more reaction sites. The term “reaction site”, as used herein, refers to a space or void (e.g., a well, chamber, reservoir, channel and the like) that is configured to allow a chemical or biochemical reaction to take place therein. Reaction sites may be closed, partially closed, open, partially open, sealed, or combinations thereof, including any temporary or transient conditions involving any of these states. In some embodiments, the reaction sites are sealed, capable of being sealed, closeable, isolated, capable of being isolated, and combinations thereof, and any combination or single condition of any temporary or transient conditions involving any of these states. The microfluidic device may include elastomeric components, such as deflectable membranes, that can form valves. In some embodiments, the substrate from which the microfluidic device is fabricated is composed of elastomeric material.

As described elsewhere herein, the microfluidic device may comprise one or more components for conducting microfluidic analyses, including components that can be utilized to conduct thermal cycling reactions, such as nucleic acid amplification reactions. Suitable amplification reactions will be familiar to persons skilled in the art, illustrative examples of which include linear amplification (e.g., a single primer) or exponential amplification (e.g., with forward and reverse primers). See, for example, WO 2010/041088 and WO 2012/038462.

In some embodiments, the microfluidic device utilizes blind channels to perform a reaction, such as nucleic acid amplification reaction. In such embodiments, the reagents that are typically deposited within the reaction sites are those reagents necessary to perform the desired type of amplification reaction. These may include some or all of primers, polymerase enzymes, nucleotides, metal ions, buffer, detectable labels and other cofactors. The sample introduced into the reaction site in such cases is the nucleic acid template. Alternatively, the template can be deposited and the amplification reagents flowed into the reaction sites. For instance, samples containing a nucleic acid template may be flowed through a first channel and the amplification reagents flowed through a second channels, or vice versa.

In some embodiments, the microfluidic device comprises (i) a first plurality of flow channels formed in an elastomeric substrate, (ii) a second plurality of flow channels formed in the elastomeric substrate that intersect the first plurality of channels to define an array of reaction sites, (iii) a plurality of isolation valves disposed within the first and second plurality of flow channels that can be actuated to isolate fluid within each of the reaction sites from fluid at other reaction sites, and (iv) a plurality of perimeter guard channels surrounding one or more of the flow channels and/or one or more of the reaction sites to inhibit evaporation of a solution therefrom.

In some embodiments, the microfluidic device will comprise one or more blind channels, which are flow channels having a dead end or isolated end such that fluid can only enter and exit the blind channel at one end; that is, there is no separate inlet and outlet for the blind channel. Such devices require only a single valve for each blind channel to isolate a region of the blind channel to form an isolated reaction site. The blind channels can also be connected to an interconnected network or array of channels such that all the reaction sites can be filled from a single, or limited number, of sample inputs. As a result of the reduction in the number of inputs and outputs and the use of only a single valve to isolate each reaction site, the space available for reaction sites is increased. Thus, such devices may advantageously include a large number of reaction sites, for example, up to tens of thousands, and can achieve high reaction site densities, for example, over 1,000-4,000 reaction sites/cm². Individually and collectively, these features significant reduce in the size the microfluidic device compared to traditional microfluidic devices.

In some embodiments, the microfluidic device will comprise a matrix design; for example, a plurality of intersecting horizontal and vertical channels to define an array of reaction sites at the points of intersection. Discrete reaction sites can also be coupled at the points of intersection to allow for the flow of fluid between reaction sites. A valve system, also referred to herein as a switchable flow array, can also be used to control the flow of fluid through the flow channels. Matrix designs can be constructed to analyze a large number of samples under a limited number of conditions. In other embodiments, the microfluidic device comprises a combination of matrix and blind channel features.

In some embodiments, the microfluidic device is a massively partitioning device, as described, for example, in WO 2004/089810 and US patent publication no. US 20050019792, each of which is incorporated by reference in their entirety. Using massively partitioning devices, a sample can be partitioned into a multitude of isolated reaction chambers, and reactions carried out simultaneously in each chamber.

In some embodiments, the microfluidic device comprises a component for controlling the temperature of the device or of a fluid therein. Such devices may be further adapted to incorporate a design feature that minimizes evaporation of a fluidic sample from reaction sites. Microfluidic devices of this type may include a number of guard channels and/or reservoirs or chambers formed within the device through which water can be flowed to increase the water vapour pressure within the material from which the device is formed, thereby reducing evaporation of sample material from the reaction sites. In an embodiment disclosed herein, a temperature cycling device may be used to control the temperature of the microfluidic devices. For example, the microfluidic device can be adapted to make thermal contact with a temperature cycling device. Where the microfluidic device is supported by a substrate material, such as a glass slide or the bottom of a carrier plate, such as a plastic carrier, a window may be formed in a region of the carrier or slide such that the microfluidic device, preferably a device having an elastomeric block, may directly contact the heating/cooling block of the temperature cycling device. In one embodiment, the heating/cooling block has grooves therein in communication with a vacuum source for applying a suction force to the microfluidic device, preferably a portion adjacent to where the reaction is to take place. Alternatively, a rigid thermally conductive plate may be bonded to the microfluidic device that then mates with the heating and cooling block for efficient thermal conduction.

It will be understood that, if the microfluidic device is to be utilized in temperature control reactions (e.g., thermocycling reactions), then the device may be fixed to a support (e.g., silicon wafer, plastic carrier, etc.). The resulting structure can then be placed on a temperature control plate, for example, to control the temperature at the various reaction sites. In the case of thermocycling reactions, the device can be placed on any of a number of thermocycling plates.

The plurality or array of channels of a microfluidic device means the such devices can achieve high throughput sample processing and/or analysis. The combination of high throughput and temperature control capabilities make certain microfluidic devices particularly useful for performing large numbers of temperature controlled reactions, such as nucleic acid amplifications (e.g., polymerase chain reaction (PCR)). However, it is to be understood that the microfluidic devices are not limited to these particular applications and can be utilized in a wide variety of other types of analyses or reactions. Illustrative examples include analyses of protein-ligand interactions, interactions between cells and various compounds and protein purification and/or fractionation (separation).

As described elsewhere herein, microfluidic devices may incorporate pumps and/or valves to isolate selectively a reaction site at which reagents are allowed to react. Alternatively, devices without pumps and/or valves may use pressure-driven flow or polymerization processes to close appropriate channels and thereby selectively isolate reaction sites. The reaction sites can be located at any of a number of different locations within the microfluidic device. For example, in some matrix-type devices, the reaction site can be located at the intersection of a set of flow channels. In blind channel devices, the reaction site can be located at the end of the blind channel.

In some embodiments, the microfluidic device can be made of a material that is relatively optically transparent. Suitable optically transparent materials will be known to persons skilled in the art. Where such material is used, reactions performed therein can be monitored using a variety of suitable detection systems located at essentially any location on or within the microfluidic device. In some embodiments, detection may occur at the reaction site itself (e.g., an isolated chamber along a blind flow filled device). Where the device is manufactured from substantially transparent materials, certain detection systems can be utilized with the device that may not be suitable with some traditional silicon-based microfluidic devices. Detection may also be achieved using detectors that are incorporated into the microfluidic device (i.e., integrated) or that are separate from the device but aligned with the region of the device to be detected. A combination of incorporated and integrated detectors may also be used.

In some embodiments, the microfluidic device utilizes the matrix design, as described elsewhere herein, comprising a plurality of vertical and horizontal flow channels that intersect to form an array of junctions. Because a different sample and reagent (or set of reagents) can be introduced into each of the channels, a large number of samples can be tested against a relatively large number of reaction conditions in a high throughput format. For example, if a different sample is introduced into each of “V” different vertical flow channels and a different reagent (or set of reagents) is introduced into each of “H” different horizontal flow channels, then “V×H” number of different reactions can be conducted at the same time. Matrix devices may include valves that allow for switchable isolation of the vertical and horizontal flow channels, as described elsewhere herein. The valves can be positioned to allow selective flow only through the vertical flow channels or only through the horizontal flow channels. As a result of the flexibility with respect to the selection of the type and number of samples, as well as the number and type of reagents, these devices can be used for conducting analyses where a large number of samples can be screened against a relatively large number of reaction conditions. Matrix devices can also optionally incorporate guard channels to assist in inhibiting evaporation of sample and reactants.

In some embodiments, high-density matrix designs can be configured to allow fluid communication between layers of the microfluidic device. For example, by having a fluid line in each layer of a two-layer elastomeric block, higher density reaction cell arrangements are possible. As will be evident to one of skill in the art, multi-layer devices can be designed to allow fluid lines to cross over or under each other without being in fluid communication. For example, a reagent fluid channel in a first layer can be connected to a reagent fluid channel in a second layer, while the second layer also has sample channels therein, the sample channels and the reagent channels terminating in sample and reagent chambers, respectively. The sample and reagent chambers can be in fluid communication with each other through an interface channel that has an interface valve associated therewith to control fluid communication between each of the chambers of a reaction cell. In use, the interface is first closed, then reagent is introduced into the reagent channel from a reagent inlet and a sample is introduced into the sample channel through a sample inlet. Containment valves are then closed to isolate each reaction cell from other reaction cells. Once the reaction cells are isolated, the interface valve is opened to cause the sample chamber and the reagent chamber to be in fluid communication with each other so that a desired reaction may take place. Persons skilled in the art would also recognize that many variations, modifications and alternatives are available, depending on the intended use of the microfluidic device.

In some embodiments, the microfluidic device comprises is adapted to react M number of different samples with N number of different reagents comprising: a plurality of reaction cells, each reaction cell comprising a sample chamber and a reagent chamber, the sample chamber and the reagent chamber being in fluid communication through an interface channel having an interface valve associated therewith for controlling fluid communication between the sample chamber and the reagent chamber; a plurality of sample inlets each in fluid communication with the sample chambers; a plurality of reagent inlets each in fluid communication with the reagent chambers; wherein one of the sample inlets or reagent inlets is in fluid communication with one of the sample chambers or one of the reagent chambers, respectively. Certain embodiments include the reaction cells being formed within an elastomeric block formed from a plurality of layers bonded together and the interface valve is a deflectable membrane; having the sample inlets be in fluid communication with the sample chamber through a sample channel and the reagent inlet in fluid communication with the reagent chamber through a reagent channel, a portion of the sample channel and a portion of the reagent channel being oriented about parallel to each other and each having a containment valve associated therewith for controlling fluid communication therethrough; having the valve associated with the sample channel and the valve associated with the reagent channel in operable communication with each other through a common containment control channel and/or having the containment common control channel located along a line about normal to one of the sample channel or the reagent channel.

In another embodiment disclosed herein, the microfluidic device may be further integrated into a carrier device, illustrative examples of which are described in US patent publication no. 20050214173, which is incorporated herein by reference in its entirety. Such carrier devices can provide on-board continuous fluid pressure to maintain valve closure away from a source of fluid pressure. In another embodiment, the microfluidic device comprises an automated system for charging and actuating valves therein. The automated system for charging accumulators and actuating valves may employ a device having a platen that mates against one or more surfaces of the microfluidic device, wherein the platen has at least two or more ports in fluid communication with a controlled vacuum or pressure source, and may further include mechanical portions for manipulating portions of the microfluidic device, for example, but not limited to, check valves.

In an embodiment disclosed herein, the microfluidic device utilises reaction volumes ranging from 10 picoliters to 100 nanoliters. In some embodiments, reaction volumes greater than 100 nanoliters can be utilized. In other embodiments, the microfluidic device utilizes reaction volumes of 10 picoliters to 1 nanoliter. In other embodiments, reaction volumes of 2 nanoliters to 100 nanoliters are utilized.

Depending on the geometry of the microfluidic device and the size of the microfluidic device and the arrangement of the channels and reaction sites therein, a range of processing site (or reaction site) densities can be utilised. In some embodiments, the microfluidic device comprises a chamber density ranging from about 100 chambers per cm² to about 1 million chambers per cm². In some embodiments, the microfluidic device comprises a chamber density of 250, 1,000, 2,500, 10,000, 25,000, 100,000 or 250,000 chambers per cm². In some embodiments, chamber densities in excess of 1,000,000 chambers per cm₂ are utilized.

In an embodiment disclosed herein, at least one of the plurality of channels is a capillary. In another embodiment, at least one of the plurality of channels is a chromatography column.

In another embodiment, the plurality of channels are configured to form (i) at least one loading channel inlet, (ii) at least one loading channel outlet, (iii) at least one buffer channel and (iii) at least one detection channel, wherein the at least one loading channel inlet is in fluidic cooperation with the at least one loading channel outlet, which in turn is in fluidic cooperation with the buffer channel, which in turn is in fluidic cooperation with the detection channel.

In another embodiment, the microfluidic device further comprises electrical contacts for coupling the device to an external power source, for example, to enable the electrokinetic manipulation of fluid therein.

As discussed elsewhere herein, the inventors have surprisingly shown that, whilst lubricin attaches or adheres to any surface, the anti-adhesive property of the lubricin coating was found to be most effective on hydrophobic, anionic and polar (uncharged) surfaces. Thus, in an embodiment disclosed herein, the plurality of channels comprise a surface selected from the group consisting of a hydrophobic surface, an anionic surface, a polar surface and combinations thereof. In an embodiment, the plurality of channels comprise a hydrophobic surface. Suitable hydrophobic surfaces or material will be familiar to persons skilled in the art, illustrative examples of which are gold, polystyrene, poly(dimethyl siloxane), and polytetrafluoroethylene. In an embodiment disclosed herein, the hydrophobic surface is selected from the group consisting of a gold surface, a polystyrene surface, a polydimethylsiloxane surface, and a polytetrafluoroethylene surface.

The ability of lubricin to bind to many different surfaces means that the surface of the microfluidic device channels may be further modified for a particular purpose or function, as required. In one embodiment, the hydrophobic surface is a thiol-modified hydrophobic surface. The inventors have surprisingly found that the anti-adhesive property lubricin was effective on a OH-thiol- or CH₃-thiol-modified hydrophobic surface and, to some extent, on a COOH-thiol-modified surface. Thus, in an embodiment disclosed herein, the plurality of channels comprise a thiol-modified hydrophobic surface. In an embodiment, the thiol is a OH-thiol or a CH₃-thiol. In another embodiment, the plurality of channels comprise a COOH-thiol-modified surface. In another embodiment, the hydrophobic surface is a silane-modified hydrophobic surface.

As used herein, reference to “a plurality of channels” is to be understood as meaning two or more channels; for example, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51 channels, and so on. In an embodiment, at least two of the plurality of channels are interconnected (i.e., in fluid communication with one another). In another embodiment, at least two of the plurality of channels are not interconnected (i.e., not in fluid communication with one another). In another embodiment, some of the plurality of channels are interconnected (i.e., in fluid communication with one another) and some of the plurality of channels are not interconnected (i.e., not in fluid communication with one another). As described elsewhere herein, the design of the microfluidic device will depend on its intended use/application.

The present inventors have also surprisingly shown that the anti-adhesive property of the lubricin coating was effective on a polystyrene surface. Thus, in an embodiment, the plurality of channels comprise a polystyrene-modified surface. In other embodiments disclosed herein, the plurality of channels comprise a surface selected from the group consisting of silica, polystyrene, polymethylmethacrylate, polycarbonate, polydimethylsiloxane and combinations thereof.

As used herein, the phrase “substantially coated” is to be understood as meaning a coating over the entire surface of a channel, or over a substantial area of the surface that is sufficient to resist nonspecific binding of protein or other unwanted biomaterial (including the formation of a biofilm) as may be required for a particular purpose. For example, in some embodiments, a coating of lubricin, or of a functional variant thereof, is only applied to a surface of a channel where detection or sensing is to be performed. This ensures that nonspecific binding of protein or other unwanted biomaterial (including the formation of a biofilm) across the detector or sensor is minimised, which would otherwise lead to deterioration of the surface and reduce the sensitivity of detection. In other embodiments, it may be more efficient to coat the surface of the plurality of channels across the entire microfluidic device; for example, by passing a solution of lubricin, or functional variant thereof, through the array of channels of the microfluidic device for a period of time and under conditions suitable for allowing the lubricin or functional variant to bind to and substantially coat the plurality of channels. In an embodiment, at least 70% of the surface of the plurality of channels is coated with lubricin, or a function variant thereof. By “at least 70%” is meant 70, 71, 72, 73, 74, 75, 76, 77, 78, 79, 80, 81, 82, 83, 84, 85, 86, 87, 88, 89, 90, 91, 92, 93, 94, 95, 96, 97, 98, 99 or 100% of the surface area of the plurality of channels.

As noted elsewhere herein, reference to “a plurality of channels” is to be understood as meaning two or more channels. Thus, in some embodiments, at least two channels are substantially coated with lubricin, or a functional variant thereof, whilst one or more other channels may remain uncoated by lubricin. For example, one or more channels may be configured to transport water or other non-biological fluid, and are therefore not exposed to conditions that would otherwise lead to biofouling. Such channels need not be treated with a resistant coating. In other embodiments, the one or more other channels may be coated with PEG. In other embodiments, some of the plurality of channels are substantially coated with native lubricin, whilst other channels are substantially coated with a functional variant thereof.

As noted elsewhere herein, the present invention is applicable to any type microfluidic device where resistance to biofouling and/or biofilm formation is desired. Therefore, the type of microfluidic device will depend on the desired application. Illustrative examples of suitable microfluidic devices, including methods for their manufacture, are described in U.S. Pat. No. 8,999,265; US patent publication no. 20150209785; U.S. Pat. No. 8,628,729; US patent publication no. 20140038224; US patent publication no. 20150185118; US patent publication no. 20110223654; WO 2008/108838; WO 2007/117987; WO 2013/102093; WO 2008/127405; WO 2010/041088; WO2012/038462; Wu et al. (2003, J. Am. Chem. Soc. 125:554-559); Chung et al. (2008, Lab Chip, 8:330-338); McDonald et al. (2002, Accounts of Chemical Research, vol 35 (7): 491-499); Chan-Park et al. (2004, Sensors and Actuators B: Chemical, 101:175-182); and Yu et al. (2009, Sensors and Actuators B: Chemical; 137(2):754-761).

As noted elsewhere herein, the type of microfluidic device and its componentry will depend on its desired application or function. Illustrative examples of suitable applications for microfluidic devices and the like include the electrokinetic flow of fluids and analytes, in-chip electrophoretic separation of analytes, surface plasma resonance, pre-concentration of analytes, protein sorting and combinations thereof.

### (i) Electrokinetic Flow

There are two common methods by which fluid actuation through channels of a microfluidics device can be achieved: pressure driven flow and electro-osmotic (or electrokinetic) flow. In pressure driven flow, fluid is pumped through the device via positive displacement pumps, such as syringe pumps. In electro-osmotic flow, the surface of the substrate channel will typically have an electric charge or modified such that a net electrical charge is present. When an electric field is applied across the channel, the ions in the charged layer move towards the electrode of opposite polarity. This creates motion in the fluid near the surface which is in turn transferred via viscous forces into convective motion through to the fluid. If the channel is open at the electrodes, as is most often the case, the velocity profile is typically uniform across the entire width of the channel. Conversely, if the electric field is applied across a closed channel (or a backpressure exists that counters that produced by the electrostatic pump), a recirculation pattern forms in which fluid along the centre of the channel moves in a direction opposite to that at the surface. In closed channels, the velocity along the centre of the channel is less than the velocity of the fluid at the surface. By virtue of its net negative charge, lubricin can be used to coat any substrate surface and thus provide an electric charge that can be used to control the electrokinetic flow of fluid via electro-osmosis. This is illustrated in the Examples disclosed herein.

### (ii) In-Chip Capillary Electrophoresis

Capillary electrophoresis is a separation technique that has been used in the separation and analysis of proteins, nucleic acid molecules and other analytes. Typically, small amounts of fluids are injected into a separation channel by using plug injection. Substances are separated based on their electrophoretic mobility, which is proportional to their charge to size ratio. Capillary electrophoresis with microfluidic devices, also referred to as “in-chip” or “on-chip” electrophoresis, offers advantages over traditional capillary electrophoresis. For example, providing an integrated injection structure enables the flow of much smaller volumes of samples than would otherwise be possible with traditional capillary electrophoresis. As a result, separation channels can be very short, which enables much faster analyses to be performed. Illustrative examples of in-chip electrophoresis devices include those described by Beyreiss et al. (Electrophoresis, 2011; 32(22):3108-14), Harrison et al. (Anal. Chem. 1992, 64:1928-1932) and Bharadwaj et al. (Electrophoresis 2002, 23:2729-2744).

Suitable capillary electrophoresis material will be familiar to persons skilled in the art, the nature of which will depend on the intended use (i.e., the analytes to be separated). An illustrative example of suitable capillary electrophoresis material is silica, more particularly monolithic silica. Examples of suitable monolithic silica substrate material will be known to persons skilled in the art, an illustrative example of which is Onyx Monolithic Si HPLC columns (Phenomenex). Other suitable monolithic materials include cellulose, cellulose acetate, ethylvinylbenzene divinylbenzene copolymer, poly(styrene-co-divinylbenzene) alumina, graphitic carbon, polyethylene, polypropylene, and polystyrene. In an embodiment, the capillary electrophoresis material is substantially coated with lubricin, or a functional variant thereof, as herein described, providing resistance to biofouling. Moreover, the electrohydrodynamic property of lubricin means that lubricin-coated capillary electrophoresis material can be used for combined electrokinetic and phase separation of analytes, such as proteins, drugs, nucleic acids, nanopraticles, and peptides.

(iii) Surface Plasma Resonance

In some embodiments, the microfluidic device may further comprise a surface plasmon resonance (SPR) sensor, such as a gold SPR sensor. Biorecognition molecules specific to a target analyte (e.g., antibodies) can be grafted to the gold surface, either through a covalent linkage or through electrostatic adsorption. Exposed regions of the gold SPR sensor can be coated with lubricin, or a functional variant therof, as herein described, to block the non-specific adsorption of an analyte to the sensor surface. A solution containing the target analyte is flowed over the sensor surface, either electrokinetically or via the application of pressure. Incident p-polarized laser light is reflected off the gold SPR sensor and is used to excite surface plasmons at the gold SPR sensor surface. The binding of an analyte to the biorecognition molecules changes the intensity of the reflected light, leading to a change in the SPR signal proportional to the amount of bound analyte. The presence of lubricin, or a functional variant thereof, reduces the amount of non-specific adsorption to the gold SPR sensor surface, leading to an enhanced signal-to-noise ratio that increases the sensitivity of the SPR sensor.

### (iv) Pre-Concentration of Analytes

In some embodiments, the microfluidic device can be used for pre-concentrating analytes. For example, electrodes are placed within a LUB-coated microfluidic channel. Pressure can be applied to drive the flow of fluid within the device. An appropriate electric potential is then applied between the two electrodes within the microfluidic channel to generate electrophoretic migration of a charged analyte (e.g. a protein, drug, nucleic acid molecule, etc.) acting in the opposite direction of the pressure driven flow of fluid. As the analyte enters the region between the two electrodes, it becomes trapped and thus becomes concentrated as more and more analyte enters this region. Once the electric potential between the electrodes is removed, a concentrated plug of analyte is released and one more migrates through the microfluidic channel with the pressure driven flow of fluid toward a sensing element.

### (v) Analyte Sorting

In some embodiments, the microfluidic device can be used for sorting analytes. For example, a mixture comprising at least two different analytes (analyte 1 and analyte 2) is placed into a LUB-coated microfluidic device consisting of a Y-shaped channel. Electrodes at each terminus of the Y shaped channel are used to generate electroosmotic flow of the fluid toward the Y-junction of the channel. Differences in the electrophoretic mobilities of the analyte 1 and analyte 2 leads to a separation as they migrate down the channel at different rates. After separation, as analyte 1 approaches the Y-junction, appropriate electrical potentials are used to generate electroosmotic flow down one channel in the direction of the Y-j unction causing analyte 1 to enter the channel. After analyte 1 has entered one channel of the Y-j unction, the electrical potentials are altered to divert the electroosmotic flow down the other channel of the Y-j unction. Analyte 2 thus enters the other channel of the Y-junction, thus sorting the two analytes into two different channels of the device.

As noted elsewhere herein, the present invention is predicated, at least in part, on the inventors' surprising finding that lubricin-coated surfaces possess an electrohydrodynamic property that makes them useful for supporting the mobility of analytes by electrokinetic processes and that this property is largely unaffected by changes in pH and analyte concentration. Thus, combined with its ability to readily self-assemble to form dense, highly stable telechelic polymer brush layers on virtually any substrate surface, and its innate biocompatibility, this finding demonstrates that lubricin is a simple, versatile, highly stable, and highly effective coating for substrate surfaces configured to control the electrokinetic flow of analytes. Thus, in another aspect disclosed herein, there is provided a method of controlling the electrokinetic flow of an analyte through a channel of a microfluidic device, the method comprising passing a fluid comprising the analyte through the channel under the influence of an electric field applied between a first position and a second position along the channel, wherein the channel is substantially coated with lubricin, or a functional variant thereof. Suitable analytes would be familiar to persons skilled in the art, illustrative examples of which include proteins (e.g., immunoglobulin) and nucleic acid molecules. In an embodiment, the analyte is a protein or a nucleic acid molecule. Methods of controlling the electrokinetic flow of an analyte through (or along) a channel, such as a channel of a microfluidic device and the like, will be familiar to persons skilled the art, an illustrative example of which is disclosed herein. In an embodiment disclosed herein, the channel comprises a surface selected from the group consisting of silica, polystyrene, polymethylmethacrylate, polycarbonate, polydimethylsiloxane and combinations thereof.

As noted elsewhere herein, the dual anti-adhesive and electrohydrodynamic properties of lubricin makes it particularly useful as an anti-adhesive coating for microfluidic devices, although it is also useful as an anti-adhesive coating for other types of sample processing devices or surfaces thereof where resistance to biofouling is desirable. For example, its dual anti-adhesive and electrohydrodynamic properties makes lubricin a useful coating for chromatographic material for the separation of analytes. Thus, in another aspect disclosed herein, there is provided a chromatographic material for the electrophoretic separation of an analyte, wherein the chromatographic material is substantially coated with lubricin, or a functional variant thereof. In another aspect disclosed herein, there is provided a chromatographic material for the chromatographic separation of an analyte, wherein the chromatographic material is substantially coated with lubricin, or a functional variant thereof. In an embodiment, the chromatographic material functions as the stationary phase. Suitable chromatographic material will be familiar to persons skilled in the art, illustrative examples of which include silicon-based material or resins. In an embodiment disclosed herein, the chromatographic material is a monolithic silicon. In some embodiments, the chromatographic material is part of a microfluidic device. However, it will be understood that the present invention is not limited by scale and is therefore applicable to the electrophoretic separation of larger volumes of analyte solutions that is often typical of chromatographic separation techniques. In some embodiments disclosed herein, the chromatographic material is selected from the group consisting of silica, polystyrene, polymethylmethacrylate, polycarbonate, polydimethylsiloxane and combinations thereof.

### Methods of Manufacturing Microfluidic Devices

In another aspect disclosed herein, there is provided a method for manufacturing a microfluidic device comprising: (i) providing a substrate having a plurality of channels configured to transport a fluid, and (ii) applying to the plurality of channels a coating solution comprising lubricin, or a functional variant thereof, under conditions to allow the lubricin or functional variant thereof to substantially coat the plurality of channels.

In an embodiment, the substrate comprises (i) at least one loading channel inlet, (ii) at least one loading channel outlet, (iii) at least one buffer channel and (iii) at least one detection channel, wherein the at least one loading channel inlet is in fluidic cooperation with the at least one loading channel outlet, which in turn is in fluidic cooperation with the buffer channel, which in turn is in fluidic cooperation with the detection channel.

Suitable methods and materials for manufacturing or fabricating microfluidic devices, including channels and arrays thereof, will be familiar to persons skilled in the art. Illustrative examples include those described in U.S. Pat. No. 8,047,829 and US patent application publication No. 20080014589, each of which is incorporated herein by reference in their entirety. In an embodiment, the plurality of microfluidic channels may be constructed using simple tubing, but may further involve sealing the surface of one slab comprising open channels to a second slab. Materials into which microfluidic channels may be formed include silicon, glass, silicones such as polydimethylsiloxane (PDMS), and plastics such as poly(methyl-methacrylate) (known as PMMA or “acrylic”), polystyrene (PS), cyclic olefin polymer (COP), and cyclic olefin copolymer (COC). Compatible combinations of materials may also be used. The microfluidic channel may be encased as necessary in an optically clear material to allow for optical excitation (resulting in, e.g., fluorescence) or illumination (resulting in, e.g., selective absorption) of a sample as necessary, and to allow for optical detection of spectroscopic properties of light from a sample, as the sample is flowing through the microfluidic channel. Illustrative examples of suitable optically clear materials that exhibit high optical clarity and low autofluorescence include borosilicate glass (e.g., Schott Borofloat™ glass; Schott North America, Elmsford N.Y.) and cyclo-olefin polymers (e.g., Zeonor™; Zeon Chemicals LP, Louisville Ky.).

In some embodiments, the microfluidic device is constructed at least in part from elastomeric materials and constructed by single and/or multilayer soft lithography (MSL) techniques and/or sacrificial-layer encapsulation methods, as previously described, for example, by Unger et al. (2000, Science 288:113-116), incorporated by reference herein in its entirety.

It will be understood by persons skilled in the art that the methods used in the fabrication of a microfluidic device may vary with the materials used. Other suitable methods of manufacturing microfluidic devices include soft lithography, microassembly, bulk micromachining methods, surface micro-machining methods, standard lithographic methods, wet etching, reactive ion etching, plasma etching, stereolithography and laser chemical three-dimensional writing methods, modular assembly methods, replica molding methods, injection molding methods, hot molding methods, laser ablation methods, combinations of methods, and other methods known in the art or developed in the future. Illustrative examples include those previously described by Fiorini and Chiu (2005, Biotechniques 38:429-46); Beebe et al. (2000, Proc. Natl. Acad. Sci. USA 97:13488-13493); Rossier et al. (2002, Lab Chip 2:145-150); Becker et al. (2002, Talanta 56:267-287; Becker et al. (2000, Electrophoresis 21:12-26; U.S. Pat. No. 6,767,706; Terry et al. (1979, IEEE Trans. on Electron Devices, v. ED-26, 1880-1886); Berg et al. (1994, Micro Total Analysis Systems, New York, Kluwer; Webster et al. (1996, Monolithic Capillary Gel Electrophoresis Stage with On-Chip Detector in International Conference On Micro Electromechanical Systems, MEMS 96:491496; and Mastrangelo et al. (1989, Vacuum-Sealed Silicon Micromachined Incandescent Light Source, in Intl. Electron Devices Meeting, IDEM 89:503-506), each incorporated herein by reference in their entirety. See also U.S. Pat. No. 5,376,252, also incorporated herein by reference in its entirety.

In some embodiments, the plurality of channels of the microfluidic device may be coated with lubricin, or a functional variant thereof, prior to or during the fabrication process. For example, where the device is fabricated by layering two or more slabs, channels may be formed onto at least one of the slabs and coated with lubricin, or a functional variant thereof, prior to layering. Alternatively, or in addition, the device is fabricated and the plurality of channels of the device are subsequently coated with lubricin, or a functional variant thereof. In some embodiments, subsequent coating with lubricin, or a functional variant thereof, will be more desirable because the layering or fabrication process may expose the device and the plurality of channels to heat, adhesive material, etc, that may adversely affect a prior coating of lubricin or a variant thereof. Suitable methods of coating the plurality of channels with lubricin, or a functional variant thereof, will be familiar to persons skilled in the art. An illustrative example is described elsewhere herein and by Greene et al. (2015, Biomaterials 53; 127-136). Thus, in another aspect, there is provided a method of preventing fouling of a channel in a microfluidic device, the method comprising coating the channel with lubricin, or a functional variant thereof.

### Fluids

As discussed elsewhere herein, the present inventors have found that lubricin is a simple, versatile, highly stable, and highly effective coating that can be used to control unwanted adhesion onto, and biofouling of, almost any type of substrate surface. Thus, it will be well understood by persons skilled in the art that the present invention is not limited to a particular process or analysis and, hence, the type of fluid will depend on the purpose of microfluidic device; that is, the nature of the process or analysis to be performed. In an embodiment disclosed herein, the fluid is a biological fluid. Illustrative examples of biological fluids include blood, serum, plasma, urine, saliva, vaginal secretions, gastric fluid, cerebrospinal fluid, semen, tears, sweat, etc., or any fluid comprising biologic material to be processes and/or detected. The fluid may comprise a cell or microorganism or a collection of cells or microorganisms (e.g., eukaryotic or prokaryotic cells or microorganisms). Illustrative examples include cells or microorganisms derived from humans, animals, plants, fungi, bacteria, viruses, protozoa, yeasts, molds, algae, rickettsia, and prions. The fluid may also comprise proteins, peptides, nucleic acids, polynucleotides (e.g., genomic DNA, mitochondrial DNA, RNA, or synthetic DNA or RNA), oligonucleotide probes, analytes, drugs, or a chemical reaction comprising one or more reagents or reaction components, such as organic and inorganic chemicals, enzymes (e.g., polymerases) and buffers. In an embodiment disclosed herein, the biological fluid is selected from the group consisting of blood, serum and plasma.

Typically, the fluid is any aqueous or lipophilic phase capable of flowing freely through at least one of the plurality of channels of the microfluidic device. For example, the device may be used to perform a cascading assay on one or more samples present within a fluid, whereby the volume and/or content of the fluid and/or the size and/or components of the sample may be made larger or smaller in the process of the cascading assay, followed by separation of the fluid into individual fluids comprising individual samples, followed by detection and analysis of the samples by the system of the present invention.

The fluid may also comprises an emulsion. An emulsion is to be understood as including a stable mixture of at least two immiscible or partially immiscible liquids. typically, immiscible liquids tend to separate into two distinct phases. A surfactant may be added to stabilize the emulsion by reducing surface tension between the at least two immiscible or partially immiscible liquids and/or to stabilize the interface. For example, an emulsion may comprise a plurality of aqueous droplets in an immiscible oil, such as fluorocarbon oil, silicon oil or hydrocarbon oil (e.g., petroleum and mineral oil) where the droplet size ranges from about 0.5 to about 5000 microns in diameter.

An “analyte”, as used herein, denotes be any substance that is to be analysed. Illustrative examples of suitable analytes include proteins, enzymes, nucleic acid molecules (e.g., DNA, RNA), cells (eukaryotic, prokaryotic) and small non-peptide molecules (synthetic or naturally-occurring). Analytes may be present in the fluid sample or they may be generated by chemical and/or biochemical processes performed within the microfluidic device (e.g., as a result of an enzymatic reaction).

All patents, patent applications and publications mentioned herein are hereby incorporated by reference in their entireties.

Those skilled in the art will appreciate that the invention described herein is susceptible to variations and modifications other than those specifically described. It is to be understood that the invention includes all such variations and modifications which fall within the spirit and scope. The invention also includes all of the steps, features, compositions and compounds referred to or indicated in this specification, individually or collectively, and any and all combinations of any two or more of said steps or features.

Certain embodiments of the invention will now be described with reference to the following examples which are intended for the purpose of illustration only and are not intended to limit the scope of the generality hereinbefore described.

### EXAMPLES

### Materials and Methods

### A. Purification of Lubricin (LUB)

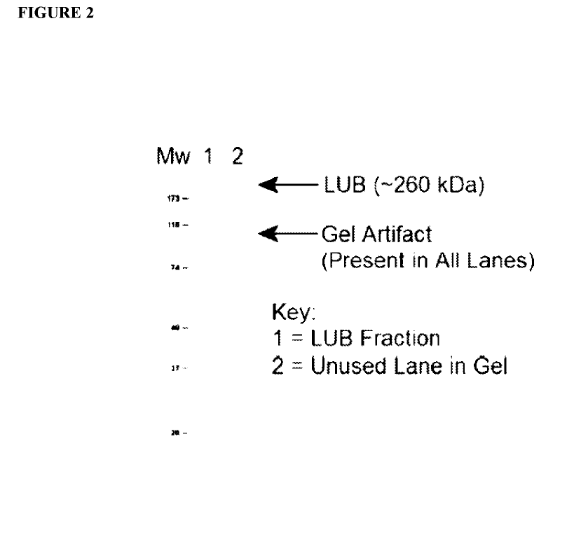

Lubricin protein was purified using a slightly modified form of the procedure described by Jay et al.^{[27]} from 500 ml of bovine synovial fluid sourced from ASIS scientific (Adelaide, Australia). The only modification of the procedure described in Jay et al.^{[27]} was the elimination of the initial membrane filtration and subsequent resuspension step (following the centrifugation of the raw synovial fluid) which was determined to be unnecessary. Instead, following centrifugation, the raw synovial fluid was diluted with a solution of 50 mM sodium acetate, 10 mM EDTA and Roche inhibitor tablets at pH 5.5 until the pH of the dilution reached pH 5.5. After this dilution, the purification proceeded as described in Jay et al.^{[27]} with the hyaluronidase digestion step. The extracted and purified LUB was analysed for purity using a density gradient SDS-PAGE Biorad gel subsequently stained with Coomasie Blue. The LUB band appeared on the SDS-PAGE gel at approximately the 260 kDa region (see FIG. 2), consistent with previous reports.^{[27]} The relative purity of the LUB (as a fraction of the total protein content) was assessed using a Biorad protein imager and spectroscopic analysis and was found to be approximately 87%. The concentration of LUB in the extracted solution was determined using the Biorad protein assay and quantified using a serial dilution of BSA as the calibration standard. After the concentration of LUB was assayed, the solution was concentrated using a Millipore Amicon Ultra Centrifugal Filter with a 100 NMWL membrane to yield a finial concentration of 100 μg/ml of protein in a buffer consisting of 25 mM Sodium Phosphate, 150 mM NaCl, 0.5 mM CaCl₂ and 0.2 mM alpha lactose at pH 7.4.

For the electrophoresis experiments, lubricin protein was purified using the procedure described in Greene et al. (Biomaterials 2015, 53:127-136) from 500 ml of bovine synovial fluid sourced from ASIS scientific (Adelaide, SA Australia). After the concentration of LUB was assayed, the solution was concentrated using a Millipore Amicon Ultra Centrifugal Filter with a 100 NMWL membrane to yield a finial concentration of 400 μg/ml of protein in a buffer consisting of 25 mM Sodium Phosphate, 150 mM NaCl, 0.5 mM CaCl₂ and 0.2 mM alpha lactose at pH 7.4.

### B. Quartz Crystal Microbalance Measurements

A Quartz Crystal Microbalance (QCM) was used to measure the mass of non-specifically adsorbed species. Measurements were performed either on bare (unmodified or chemically modified) gold sensor surfaces or onto LUB coated (unmodified or chemically modified) sensor surfaces. All QCM experiments in this study were performed in a E4 QCM-D (Q-sense, Biolin Scientific, Sweden) using a flow cell attachment with flow driven by a peristaltic pump. The QCM technique is a well-established method for making semi-quantitative measurement of the mass of protein (and other biomolecules) adsorbing to surfaces and is widely used to evaluate the efficacy of anti-adhesive coatings^{[9, 12, 34-36]}. The mass density of proteins (or other molecules) adsorbing to the surface results in a shift in the fundamental resonance frequencies of the oscillating quartz crystal sensor which is proportional to the change in mass of the crystal (i.e., mass of crystal+mass of adsorbed proteins). The well known Sauerbrey equation^{[34]} provides a convenient way of calculating the change in mass, Δm, of the quartz crystal sensor from the resonant frequency shift, ΔF:

$$\frac{Δ F}{n} = - \frac{2 {F}_{0}^{2}}{A \sqrt{{t}_{q} {ρ}_{q}}} Δ m = - C Δ m \qquad ( 1 )$$

where n, Fₒ, A, t_{q}, and ρ_{q} are the overtone number (n=7 in this work), fundamental frequency of the quartz sensor (Fₒ=5 MHz), the surface area of the piezoelectric region of the sensor, the sensor thickness, and the sensor density respectively. For this system C=17.7 ng cm⁻² Hz⁻¹ and is a material constant valid for a quartz crystal sensor with a fundamental frequency of 5 MHz.

It should be noted that the Sauerbrey equation is only quantitatively valid in the case where the adsorbed films are rigid, elastic and in air^{[34]}. Viscoelastic dampening of the oscillating crystal due to viscous dissipation in adsorbed, non-rigid films in fluid (e.g., layers of adsorbed proteins) will result in some deviation of the mass calculated by the Sauerbrey equation from the actual mass of material adsorbed to the crystal. For this reason, the Sauerbrey equation will underestimate the mass of adsorbed protein (or biomolecule) films in liquids. Despite this underestimation of the mass, the Sauerbrey equation is now routinely used to make semi-quantitative measurements of the amount of protein adsorbing to surfaces and qualitative comparisons between different surfaces.

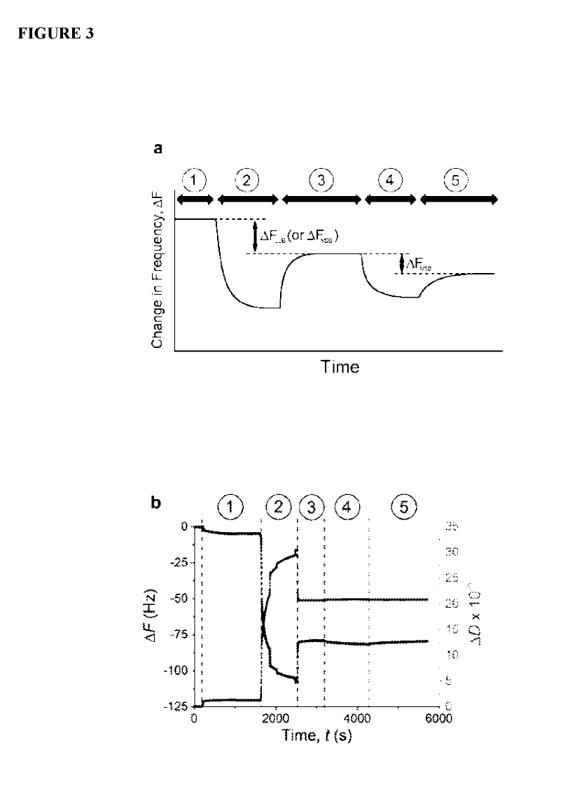

A representative schematic of the temporal change in frequency in a typical QCM measurement is shown in FIG. 3a and a representative experiment (performed in PBS buffer at pH 7.4) showing how the measured frequency and dissipation change in time during the measurements (FIG. 3b). At stage (1), the QCM crystal is equilibrated with buffer (at the desired pH) at a constant flow rate of 300 ml/min until a stable frequency baseline is achieved. At stage (2), either 100 ml if LUB protein solution or 1 ml of the protein solution (e.g., IgG, bovine serum albumin (BSA), blood plasma) at the same pH as the buffer used in stage (1) is flowed into the QCM flow cell. Once the all the protein solution has been flowed into the flow cell, the flow is stopped for an incubation period of 20 min (3). After this incubation period, the surface is rinsed by flowing fresh PBS buffer into the flowcell at a constant rate of 300 ml/min until a new stable frequency baseline is achieved. The difference in the frequency baselines measured at stage (1) and (3) is the change in frequency (used to calculate the adsorbed mass density in Eqn. (1)) due to LUB adsorption ΔF_{LUB} (in experiments involving lubricin) or the non-specific adsorption of the target protein ΔF_{NSA} on non-LUB coated surface. Only experiments looking at adsorption onto LUB coatings continue on to stage (4) at which point 1 ml of the protein solution (e.g., IgG, BSA, Blood plasma) at the same pH as the buffer used in stage (3) is flowed into the QCM flow cell at a constant rate of 300 ml/min. Once the all the protein solution has been flowed into the flow cell, the flow is stopped for an incubation period of 20 min. At stage (5), the surface is rinsed by flowing fresh PBS buffer into the flow cell at a constant rate of 300 ml/min (until a new stable frequency baseline is achieved. The difference in the frequency baselines measured at stage (3) and (5) is the change in frequency (used to calculate the adsorbed mass density in Eqn. (1)) due to the nonspecific adsorption of the target protein, ΔF_{NSB}, on the LUB coated surface.

For most of the experiments using LUB, the LUB layer was adsorbed to the sensor surface immediately before the non-specific adsorption measurement (i.e., at stage ‘2’ in FIG. 3b) with the only exception being the LUB coating aging experiments described in the ‘LUB aging experiment’ section). The LUB coating was applied onto the sensor surfaces via adsorption from a 100 μg/ml buffer solution of LUB described in the previous section. This buffer was slightly different from the PBS buffer (10 mM sodium phosphate, 137 mM NaCl, 2.7 mM KCl) used in the other stages of the experiment (e.g. stage ‘a’ and ‘c’ shown in FIG. 3). However, this difference in buffer compositions did not affect the measurements of the adsorbed LUB density which were calculated from the difference in the baseline frequencies at stages 1 and 3 in FIGS. 2a and b after each had equilibrated in the same PBS buffer. Because of the limited supply of LUB and the large number of measurements performed in this study, a method was devised to achieve saturated coverage of LUB on the sensor surface using a minimal amount of LUB solution (˜150 μl). The LUB solution was flowed into the QCM at a slow rate of 50 μl/min. Once the frequency of the QCM sensor began to decrease (indicating the adsorption of LUB to the sensor surface), the flow was halted. Once the frequency of the QCM sensor began to settle into a new, stable value, the flow was restarted again for approximately 20 seconds before the flow was again halted. This process was repeated several more times until the entire 150 μl of LUB solution had been passed through the QCM flow cell. In order to remove any LUB that was not strongly adhered to the sensor surface PBS solution was then flowed through the flow cell at a constant rate of 300 μl/min until the frequency values of the QCM sensor settled in to a constant value (typically 10-30 minutes).

In these experiments, the non-specific adsorption of bovine serum albumin (BSA; ≤98% purity; Sigma) and goat immunoglobulin G (IgG; ≤98% purity; Sigma) proteins in PBS solution at various pH values was measured. Also investigated was the nonspecific adsorption of the fouling constituents of a 50% dilution of human blood plasma in PBS (pH 7.4). Ethical approval for the collection of blood was obtained from Deakin University Melbourne, Australia (EC32-2000) and the Royal Children's Hospital Parkville, Australia (ERC 2025B). Ten milliliters of whole blood was collected in BD Vacutainer vials containing sodium heparin as an anticoagulant. The blood samples were diluted with equal volumes of PBS, layered over the 15 ml of Ficoll-Paque Plus (GE Healthcare Life Science, Australia) and centrifuged for 40 min at 400 g to isolate blood plasma.

Due to the limited supply of LUB available for this study, the large volumes of LUB required for each experimental measurement, and the large number of different experiment measurements performed in this study (a total of 44 separate measurements using LUB), only two separate and independent measurements were performed under each experimental condition (e.g., pH, target protein, modified surface, etc.). Little variation in the measured adsorbed masses was found between the two separate measurements. The error bars shown in FIGS. 3-5 therefore represent the maximum and minimum masses measured in the two different measurements while the data point represents the average.

### C. Cleaning of QCM Sensors

Prior to experiments (or subsequent chemical modification), batches of up to 5 QCM sensors were cleaned to remove any contamination. Gold coated quartz crystal microbalance sensors were first cleaned by submersion in a 3:1:1 part by volume solution of water, 30% solution of aqueous ammonia, and 30% hydrogen peroxide for 20 minutes at 70° C. After cleaning, the sensors was then rinsed thoroughly first in DI water and then in clean, filtered isopropyl alcohol before being dried in a stream of nitrogen gas. QCM crystals modified with spin coated polymer films of polymethyl methacrylate (PMMA) and polystyrene (PS) were first immersed in a 1% wt. solution of Deconex 11 (Borer Chemie AG, Zuchwil, Switzerland) in DI water for 30 minutes at 30° C. The sensors were then rinsed thoroughly with DI water before being soaked in 100 ml of DI water for another 2 hours. After the soak, the sensors were rinsed with absolute ethanol before being dried in a stream of nitrogen gas.

### D. Modification of Gold Sensor Surfaces

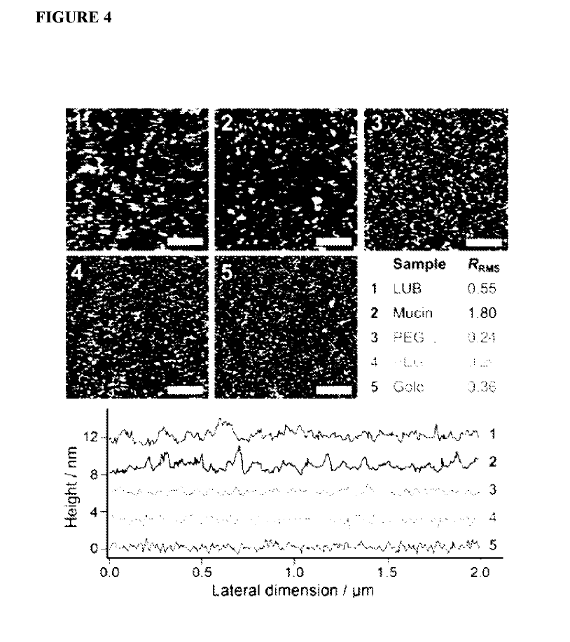

For experiments involving layers of pig gastric mucin (mucin from porcine stomach Type III; Sigma), a 5 mg/ml solution of mucin was prepared in PBS at pH 7.4. The solution was then centrifuged at 10,000 rpm for 10 min to remove aggregated protein. The resulting concentration of mucin following centrifugation was not assessed; however, the concentration was sufficient to achieve saturation of the gold sensor surface as verified by AFM (see FIG. 4). The mucin was deposited onto the sensor surface via adsorption from solutions which was performed at stage (2) in FIGS. 3a and 3b by flowing 1.0 ml of centrifuged mucin solution into the QCM flow cell at a rate of 50 ml/min.

For other experiments, sets of 5 gold coated QCM sensors were modified with different self-assembled monolayers (SAMs) of functional thiol molecules which are listed in Table 1 together with their abbreviated name, chemical functionality, and static water contact angles (and supplier) as well as two different thiol functionized PEGS having molecular weights of 356 (o-(2-Mercaptoethyl)-o0-methyl-hexa(ethylene glycol); ≤95% purity; Sigma) and 2000 (Polyethylene glycol methyl ether thiol; Sigma). Immediately after cleaning (as described above), the sensors were submerged in 10 ml of a 1 mg/ml thiol solution in methanol for 24 hours. The sensors were then rinsed with an excess of clean methanol before being dried under a stream of nitrogen gas. The thiol modified sensors were then used immediately for experiments.

Gold sensor surfaces modified with thin, spin coated polymer films of PMMA and PS were supplied by Q-Sense, Biolin Scientific.

### E. Contact Angle Measurements

Contact angle measurements were performed using a Kruss DSA100 equipped with drop shape analysis software. Experiments were performed in air using deionized water. The contact angles of 5 μl water drops on the unmodified and modified gold sensor surface were determined by fitting the drop profile to a tangential fitting algorithm.

### F. Atomic Force Microscopy Imaging

Surfaces were imaged in contact mode in liquid using a JPK Nanowizard 3 AFM. The instrument is equipped with capacitive sensors to ensure accurate reporting of height, z, and x-y lateral distances. The cantilevers used were Bruker MSCT model contact mode levers, with nominal resonant frequencies of 38 kHz and spring constants of 0.1 N/m respectively. Imaging was performed in the same buffer solution throughout, and with a force set-point of <1 nN. In post processing, images were ‘flattened’ by the removal of a straight line to ensure coplanarity. No further manipulations were performed.

### G. LUB Aging Experiment

In order to evaluate the stability of LUB anti-adhesive coatings over time when stored under dry, ambient conditions, 6 QCM gold coated sensors were coated with a saturated layer of adsorbed LUB using the technique described in the ‘QCM measurements’ section. The adsorbed mass of LUB was monitored in the QCM during the deposition to insure that a saturated mass of adsorbed LUB was achieved. After the rinsing step (step ‘3’ in FIGS. 3a and b), the LUB coated sensors were rinsed briefly with DI water and then removed from the QCM and placed under vacuum in a desiccator. At 0.22, and 62 days, one of the LUB coated QCM sensors was removed from the vacuum desiccator and the non-specific adsorption of BSA to the aged surfaces was measured in the QCM. The remaining QCM sensors were then stored under atmospheric conditions (undessicated) for an additional 60, 101, and 119 days (or a total of 122, 163, and 181 days of aging) before having the non-specific adsorption of BSA measured in the QCM as before.

### H. Chemicals

The electrophoresis experiments utilized a number of different run buffer systems, all of which were prepared using reagent grade materials. The run buffers were prepared include 2-(N-morpholino)ethanesulfonic acid buffer (MES; pH 5.0), 3-(N-morpholino)propanesulfonic acid buffer (MOPS; pH 7.2), sodium phosphate buffer (Sodium Phosphate; pH 7.2, pH 8, and pH 12), and Trisaminomethane buffer (Tris; pH 9). All run buffers were prepared to the same electrolyte concentration of 15 mM and filtered using a 0.22 μm cellulose acetate syringe filter.

Experiments investigating the migration and non-specific adsorption of protein in LUB coated capillary and microfluidic channels were performed using solutions of chromatographically purified bovine serum albumin (BSA; Sigma-aldrich, ≥98%), reagent grade goat Immunoglobulin G (IgG; Sigma-Aldrich, ≥95%), and Alexa Fluor® 488 labelled Chicken Anti-Rabbit IgG (Life Technologies; whole antibody). All protein solutions were prepared in 15 mM MOPS buffer at pH 7.2 at specific concentrations provided in the text, figures, and figure legends.

### I. Capillary Electrophoresis

Capillary electrophoresis (CE) measurements were used to measure the electro-osmotic flow and zeta-potential (ζ.) in lubricin-coated silica and PTFE capillaries. All CE experiments were performed on an Agilent 7100 CE system with detection using a DAD (Agilent Technologies, Germany) in a CZE configuration using a direct UV absorbance detector at a wavelength of 254 nm. OpenLAB CDS ChemStation Edition software for Windows 7 was used for instrument control and all data acquisition. This study investigated two different capillary systems: a 28 cm (22 cm to detector) silica capillary having an inner diameter of 75 μm and a 34 cm long (28 cm to detector) PTFE capillary having a 100 μm inner diameter. Before coating with lubricin, both the silica and PTFE capillaries were cleaned by pre-rinsing with a solution of 0.1 M KOH for 5 min followed by MilliQ water for 5 min using high pressure in the forward direction. To coat the capillaries with lubricin, the silica and PTFE capillaries were filled (using high pressure) with a 100 μg/ml solution of lubricin and allowed to sit idle for 10 minutes to give the lubricin time to self-assemble into an ordered polymer brush layer. The capillaries were then flushed with MilliQ water for 5 min using high pressure to remove any unbound lubricin molecules. Before performing a measurement, the capillaries were equilibrated to the experimental buffer conditions by flushing them with run buffer for 5 min using high pressure.

The electro-osmotic flow (EOF) velocity, v_{EOF}, within a lubricin-coated capillaries was determined by measuring the migration time of acetone, an electrically neutral molecule, through the capillaries under the action of an applied electric field using the following expression:

$${v}_{EOF} = \frac{{L}_{detector}}{{t}_{m}}$$

where L_{detector} is the length of the capillary to the detector, and tₘ is the experimentally measured migration time for the injected acetone to reach the detector. The acetone EOF marker was added to a small aliquot of the run buffer to a concentration of 1% wt and was introduced into the capillary using hydrodynamic injection for 5 seconds. The electro-osmotic mobility, μ_{EOF}, is obtained by normalizing v_{EOF} by the electric field strength E=V/Lₜₒₜₐₗ:

$${μ}_{EOF} = \frac{{v}_{EOF}}{E} = \frac{{L}_{detector} \text{/} {t}_{m}}{V \text{/} {L}_{total}}$$

where Lₜₒₜₐₗ is the total length of the capillary and V is the applied voltage.

One of the most important properties in any electrohydrodynamic process is the surface zeta-potential, ζ. The zeta-potential indirectly describes the electrostatic double layer surrounding the surface and, while it can't be directly measured, it is routinely calculated using system appropriate models. So long as the inner diameter of the capillary is at least 7 time larger that the electrostatic double layer thickness (as is the case for the capillaries used in these experiments), the EOF creates a flat, ‘plug flow’ velocity profile which allows the zeta-potential on the charged inner wall to be calculated from EOF velocity measurements using the following relationship:

$${v}_{EOF} = \frac{{ɛ}_{0} ɛ ζ}{η} E$$

where ε₀ and ε are the vacuum permittivity and medium dielectric constant respectively and η is the medium viscosity.

### J. Microfluidic Measurements

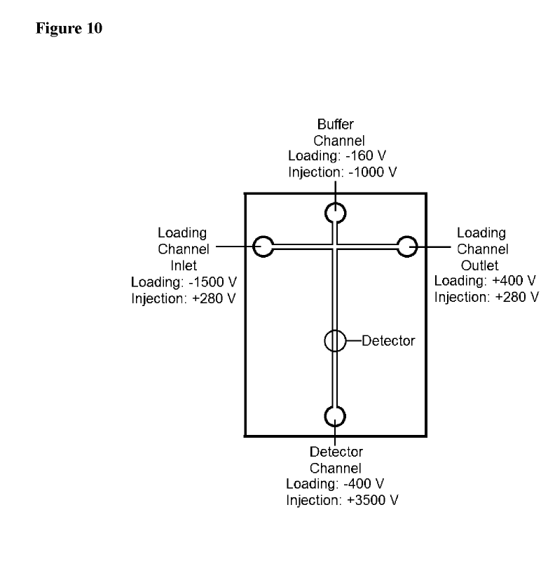

Microfluidic experiments were conducted using a hybrid glass/polydimethyl siloxane (PDMS) devices in a ‘cross-channel’ chip configuration having four reservoirs defining the ‘Loading Channel Inlet,’ Loading Channel Outlet,′ Buffer Channel,′ and ‘Detector Channel’, as illustrated by the schematic in FIG. 10. The PDMS used in these devices were not modified in any way (e.g. via oxygen plasma treatment) post-curing. Before performing the microfluidic experiments, a glass/PDMS device was coated with lubricin by filling the device with a 100 μg/ml solution of purified lubricin and allowed to sit idle for approximately 10 minutes to give lubricin time to self-assemble into an ordered polymer brush layer. The device was then rinsed with excess 15 mM MOPS buffer (pH 7.2) to remove any unbound lubricin molecules from the microfluidic device. The device remained filled with MOPS buffer until the experiments.

Microfluidic measurements were performed using 2 mg/ml solutions of Alexa Fluor® 488 labelled Chicken Anti-Rabbit IgG in MOPS buffer (pH 7.2; see ‘Chemicals’ section herein). An experiment designed to compare the non-specific adsorption of a non-coated and lubricin-coated glass/PDMS microfluidic chip was performed. In this experiment, both uncoated and lubricin-coated devices were filled with a 2 mg/ml solution of Alexa Fluor® 488 labelled Chicken Anti-Rabbit IgG in MOPS buffer using a syringe. After a period of 5 minutes, the uncoated and lubricin-coated devices were rinsed with copious amounts of clean MOPS buffer and the residual fluorescence was imaged using a bright field fluorescence microscope. Images were obtained using an in situ CCD camera using various exposure times. Other than the exposure time, all images were collected at using the same camera settings (e.g. gain, contrast, etc.). The fluorescence intensity of the images was quantified using a line-trace of the colour intensity using ImageJ software for the analysis.

In another experiment, a 0.5 mg/ml solution of Alexa Fluor® 488 labelled Chicken Anti-Rabbit IgG in MOPS buffer (pH 7.2) was electrohydrodynamically loaded, injected, and fluorescently detected using a lubricin coated device. For this experiment, the lubricin-coated device was filled with MOPS buffer and 5 μl of Alexa Fluor® 488 labelled Chicken Anti-Rabbit IgG was added to the reservoir of the ‘loading channel inlet’ (see FIG. 1). The electrohydrodynamic loading and subsequent injection of the protein was achieved by applying potentials to electrodes submerged in the reservoirs of the four channels of the device, as indicated in FIG. 10 next to the headings ‘Loading’ and ‘Injection.’ A fluorescence microscope was used to visualize the loading and injection of the protein while the detection of the fluorescent protein after injection was carried out using a photomultiplier tube which measured the fluorescence intensity within the detector channel at a length of 3 cm from the intersection of the two channels.

### Results and Discussion

### Example 1—Lubricin (LUB) Protein Inhibits Non-Specific Binding of Immunoglobulin and Serum Albumin

The non-specific binding properties of adsorbed LUB layers were evaluated using the QCM-D technique and compared against the properties of unmodified gold surfaces, two different PEG SAMs, and adsorbed layers of pig gastric mucin (Mucin) which serves as a model glycoprotein. The uniformity of the adsorbed LUB, Mucin, and PEG layers on gold films were assessed by imaging with AFM and are shown in FIG. 4. The AFM images in FIG. 4 show that the self-assembled PEG films are free of “holes” or other defects, and that the surface coverage can be considered to be complete. The morphology of the adsorbed LUB layer from AFM is similar to that seen for high LUB concentrations on highly-ordered pyrolitic graphite (HOPG)^{[38]}. For the adsorbed amounts seen in this study, the surface appeared comparatively defect-free, and the apparent surface texture was apportioned to fluctuations in the surface of the adsorbed LUB layer rather than holes per se. For LUB, the fact that a ˜100 nm layer^{[24]} retains a characteristic RMS roughness (RRMS)<1 nm indicates a dense and conformal coverage of the surface.

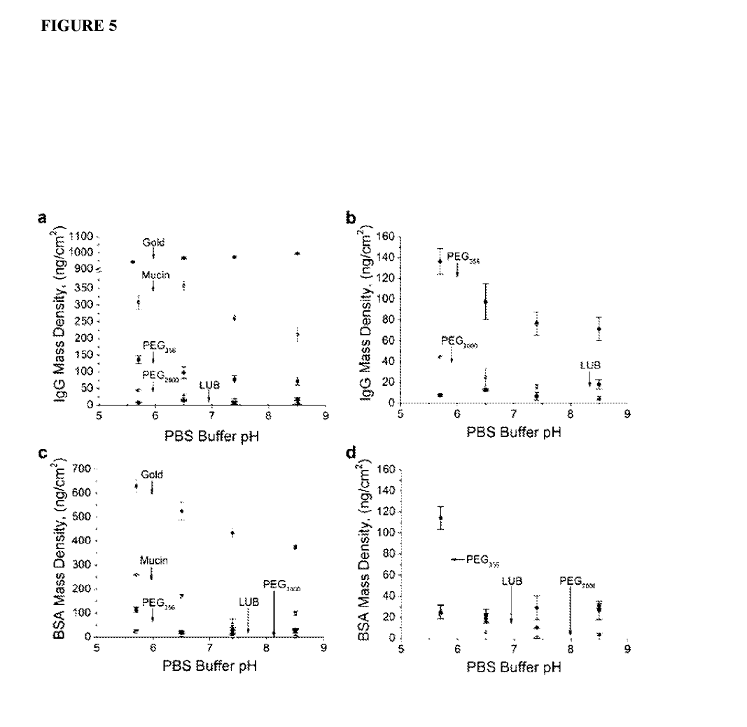

LUB against solutions of 0.5. mg/ml of goat IgG (FIGS. 5a and b) and 2.0 mg/ml of BSA (FIGS. 5c and d) in PBS solution were first tested at four different pH values between 5.7 and 8.5 (i.e., the effective buffering range). The pH was varied in this set of experiments in order to assess whether or not any electrostatic interactions arising from LUB's large anionic charge, carried (mostly) by the sialic acid terminated glycans located primarily within its central mucin domain, have any influence upon its ability to prevent the non-specific adsorption of fouling proteins. Both IgG and BSA protein were chosen for this study because they represent major protein components of whole blood and are commonly used in many immunoassay and biosensor applications.

With respect to IgG protein (see FIGS. 5a and 5b), it is clear that the adsorbed LUB layers were highly effective at preventing the non-specific binding of IgG across the entire pH range tested. At pH 7.4 (i.e., physiological pH), the LUB was able to reduce the mass of non-specifically bound IgG by approximately 99.3% relative to the unmodified gold surface. Surprisingly, despite the large amount of negative charge within the LUB mucin domain (the pKa=2.60 for sialic acid^{[43]}), changing the pH of the PBS solution from acidic to basic had little influence on the amount of IgG adsorbing to the surface with only a slight increase in binding observed at pH 8.5. This relative insensitivity to pH of the non-specific binding properties of the LUB layers is in sharp contrast to the non-specific binding properties observed in the pig gastric mucin layers, which changed significantly with changes in the solution pH. The LUB layers were significantly better at blocking the non-specific binding of IgG even though the two molecules are both highly glycosylated and structurally similar.

The LUB layers were also significantly better at blocking the adsorption of IgG than the low molecular weight PEG₃₅₆ over the entire pH range, but only marginally better than the higher molecular weight PEG₂₀₀₀ at physiological and acidic pH (at basic pH 8.5, the PEG₂₀₀₀ performed marginally better). However, despite lacking an electrostatic charge, both the low and high molecular weight PEGs showed a clear pH dependence on the total amount of non-specifically bound IgG with the amount of binding increasing from pH 8.5 to pH 5.7 by approximately 90% and 800% for the PEG₃₅₆ and PEG₂₀₀₀ respectfully. Because the mechanism for the prevention of non-specific binding of proteins to PEG chains is believed to arise from the steric repulsion produced by the strongly bound hydration layer around the PEG molecule,^{[44]} such a strong pH dependence on the non-specific binding to the PEG SAMs is both unusual and unexpected. To our knowledge, this pH dependence has not been reported elsewhere.

The results for BSA (FIGS. 5c and 5d) were similar to those observed for IgG. The data show that LUB layers were highly effective at preventing the non-specific binding of BSA protein over the full range of pH values tested. Compared with the low and high Mw PEG SAMs (FIG. 4d), the LUB layers were found to be as effective or slightly more effective than the PEG₃₅₆ SAM and slightly less effective than the PEG₂₀₀₀ SAM at blocking the adsorption of BSA. As previously observed in the IgG system, the solution pH had very little impact upon the amount of BSA binding to the LUB layers. A pH dependence on the observed non-specific binding of BSA to both the PEG₃₅₆ and PEG₂₀₀₀ SAMs, particularly at the lowest pH of 5.7, was apparent. The LUB layer was found to be significantly better at blocking the adsorption of BSA compared with the Mucin (FIG. 5c) which again showed a strong pH dependence similar to what was previously observed in the IgG system (FIG. 5a).

The non-specific adsorption of LUB layers and PEG₃₅₆ and PEG₂₀₀₀ SAMs on gold were then evaluated against a 50% dilution (in order to lower its viscosity) of human blood plasma in PBS (pH 7.4). While both BSA and IgG are major constituents of blood plasma, also present are various clotting factors and platelets that have a high affinity for many different kinds of surfaces and are often difficult to block. Often, anti-adhesive coatings that are effective against components of blood plasma individually are much less effective against the same components collectively^{[35]}. As shown in FIG. 6, compared to the bare gold surface, both the LUB and PEG SAMs layers led to a significant reduction in the measured non-specific adsorption from diluted blood plasma.

### Example 2—Effect of the Underlying Substrate on LUB Adsorption and its Anti-Adhesive Properties

A third series of QCM experiments was carried out to assess how the chemistry and interfacial properties of the underlying substrate affects the amount of LUB adsorption and the anti-adhesive properties of the adsorbed LUB layers. In these experiments, the gold surfaces of the QCM sensors were modified with either SAMs of thiol molecules terminated with different functional groups (OH—, CH₃—, COOH—, NH₂—) or a spin coated polymer thin film (PMMA, PS). The equilibrium contact angles of deionized water measured for the various modified surfaces are provided in Table 1, below:

Table 1 provides the IUPAC name of the functional thiol molecules and polymers used to modify the gold sensor surfaces, the corresponding abbreviation for each modified surface, and the measured equilibrium water contact angle (with the standard deviation in the parenthesis), θ_{water}, for each of the surfaces used in the adsorption study shown in FIG. 6.

TABLE 1

| Surface Modification | Abbreviation | θ_{water} (S.D.) | |
|---|---|---|---|
| Bare (unmodified) Gold ^{a} | Gold | 67.4° | (3.3) |
| 11-mercapto-1-undecanol ^{b} | OH-thiol | 16.2° | (2.4) |
| 1-undecanethiol ^{b} | CH₃-thiol | 104.1° | (4.1) |
| 16-mercaptohexadecanoic acid ^{b} | COOH-thiol | 20° | (2.6) |
| cystamine hydrochloride ^{b} | NH₂-thiol | 43° | (3.6) |
| Polymethyl methacrylate ^{a} | PMMA | 71° | (4.3) |
| Polystyrene ^{a} | PS | 93° | (4.1) |

^{a} Supplied by Q-sense, Biolin Scientific, Stockholm Sweden
^{b} Supplied by SigmaAldrich

In these experiments, three different adsorption measurements were performed on each unmodified and modified gold surface in the QCM which have been compiled in FIG. 7a. The first measurement quantifies the non-specific adsorption of IgG from a 0.25 mg/ml solution in PBS at pH 7.4 onto the bare unmodified or modified sensor surfaces in order to determine the surface's intrinsic affinity for adsorbing IgG. Second, the amount of LUB adsorbed from a 100 μg/ml solution in LUB buffer at pH 7.4 to the unmodified or modified sensor surfaces was measured in order to assess the binding affinity (and saturated adsorbed mass density) of LUB to surfaces with different chemical and wetting properties. Finally, the non-specific adsorption of IgG (0.25 mg/ml solution in PBS at pH 7.4) on these same adsorbed LUB layers were measured in order to gauge the effectiveness of the LUB layer at preventing the further adsorption of IgG.

A plot of the change in dissipation ΔD vs. the change in frequency ΔF, shown in FIG. 7b, indicates that the relationship between the adsorbed LUB mass and resulting viscoelastic dissipation is very similar for all of the modified surfaces measured. This similarity in the relationship between dissipation and frequency may suggest that, mechanistically, the adsorbing LUB molecules are binding and organizing in a similar fashion on all of the substrates. Since LUB is known to self-assemble into telechelic, polymer brushlike layers on CH3-thiol, OH-thiol, and NH2-thiol modified gold surfaces (although it was found to be less perfectly ordered on the OH-thiol and NH2-thiol surfaces), it is reasonable to infer that LUB most likely also self-assembles into similar brush-like layers (albeit, of varying degrees of ‘order’) on the other substrates tested as well.

From FIG. 7a, it is clear that the apparent mass of IgG and LUB protein adsorbed to the different bare modified surfaces varied significantly and was influenced, to some degree, by the chemical, electrostatic, and wetting properties of the surface. Little correlation was found between the affinities of IgG and LUB to the various modified surfaces—thus, a surface leading to a relatively higher (or lower) adsorbed mass of IgG does not necessarily also result in a similar higher (or lower) adsorbed mass of LUB.

LUB was found to adsorb in the highest amounts to the hydrophobic bare gold, CH₃-thiol, and PS modified surfaces. A similarly high mass of adsorbed LUB was also measured on the hydrophilic and negatively charged COOH-thiol modified surface. The high apparent adsorption of LUB to the hydrophobic surfaces may arise from strong hydrophobic interactions between non-polar amino acid residues that reside almost exclusively within the globular end domains regions of the molecule.^{[27]} Since these end domains are small relative to the size of the LUB molecule, adsorbing molecules occupy a relatively small area of the surface which enables the molecules to pack more densely on the surface leading to a telechelic brush layer that exposes only the mucin domain ‘loop’ to the solution. The similarly high adsorption of LUB on the anionic COOH-thiol surface may, at first, seem counter-intuitive given that the LUB molecule possesses a very high density of charged species, nearly all of which are negatively charged, which might be expected to give rise to a large electrostatic repulsion that would inhibit adsorption. However, the vast majority of LUB's negative charge carriers (e.g., sialic acid) are present within the central ‘mucin’ domain and, while somewhat balanced by the presence of lysine residues collocated in the repeated KETAPTT motif, negative charge still predominates.^{[27]} On the other hand, the globular end domains of the LUB molecule are more charged balanced and far less glycosylated.^{[27]} Consequently, this regionally specific charge and glycan distribution in the LUB molecule gives rise to the concomitant electrostatic repulsion of the central mucin domain and attraction of the globular end domains. This results in the specific adsorption of LUB to the surface through its end domains and the formation of a telechelic brush-like layer similar to that observed on hydrophobic surfaces. The ability of LUB to adsorb ‘specifically’ to the hydrophobic and negatively charged modified surfaces as a dense, telechelic brush layer probably explains the enhanced ability of these layers to prevent the subsequent adsorption of IgG. Indeed, with the exception of the bare gold surface, no detectable adsorption of IgG to the CH₃-thiol, COOH-thiol, or PS modified surfaces was observed.

In contrast to the negatively charged COOH-thiol surface where the LUB adsorbs specifically to form a telechelic brush, a significantly lower apparent adsorbed mass of LUB was measured on the positively charged NH₂-thiol modified surface. This large difference in the adsorbed masses is likely to be due, at least in part, to a decrease in the conformational specificity of the adsorbing LUB molecules that hinders its ability to organize into an ordered telechelic brush layer. A small number of LUB molecules adsorbing to a NH₂-thiol modified surface are likely to do so not only through the globular end domains, but also, to some extent, through the negatively charged mucin domain causing the molecule to lay flat against the positively charged surface or adsorb ‘up-side-down’ with their adhesive end-domains extended into solution. Consequently, these non-specifically adsorbed LUB molecules may occupy a larger area of the available surface limiting the achievable density of LUB in the adsorbed layer. Because the LUB can adsorb to positively charged surfaces through its mucin domain, the resulting unbound end domains may then function as sites that can capture IgG molecules and bind them to the adsorbed LUB layer. While still effective as an anti-adhesive on the positively charged surface (the reduction in IgG adsorption on the LUB coated NH₂ thiol surface is still 94% compared with the uncoated surface), it is possible that a small number of globular domains may be free (i.e. not ‘stuck’ to the surface). These free globular end domains, which are similar to proteins involved in cell adhesion, may function as sites that allow IgG molecules to bind to the adsorbed LUB layer. While still effective as an anti-adhesive on the positively charged surface (the reduction in IgG adsorption on the LUB coated NH₂-thiol surface is still 94% compared with the uncoated surface), the amount of non-specific adsorption is high compared to the other LUB surfaces tested.

A similar non-specificity of adsorption may be responsible for the (relatively) poorer adsorption of LUB and anti-adhesive properties of the adsorbed LUB layer on the PMMA-modified surfaces which were similar to those observed on the NH₂-thiol surfaces. The PMMA molecules are rich in hydrogen bond accepting sites while the galactose and sialic acid groups found within the glycosylation layer of the LUB mucin domain are rich in hydrogen bond donor sites. It is possible that hydrogen bonding between the mucin domain and the PMMA surface may lead to adhesive interactions between the mucin domain and PMMA that inhibit/disrupt the ability of adsorbing LUB molecules form organizing into a telechelic brush-like layer in a similar fashion to what was observed on the NH₂-thiol surfaces. Similar hydrogen bonding between bovine submaxillary gland mucin (hydrogen bond ‘acceptor’ rich) has been reported elsewhere.^{[47]} Again, a small number ‘free’ globular end domains would function as potential binding sites for IgG.

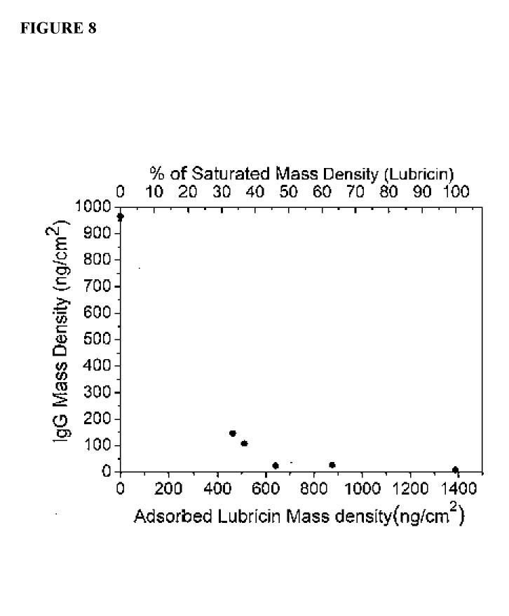

Finally, the lowest adsorbed masses of LUB was measured on the OH-thiol modified surfaces which is highly hydrophilic, polar, but uncharged. The low adsorbed mass of LUB onto the hydrophilic but uncharged surface probably reflects the absence of strong and long ranged electrostatic or hydrophobic interactions between LUB molecules and the surface. The lower LUB adsorption is most likely achieved through weaker interaction (e.g., van der Waals forces); however, the fact that the adsorbed LUB layer still prevents nearly all of the non-specific adsorption of IgG strongly suggests that LUB primarily binds to the polar, uncharged surface through its globular end domains forming a less dense and ordered telechelic brush-like layer. The high effectiveness of the LUB layer on the OH-thiol surfaces is therefore due to the relative low native affinity of IgG to the OH-thiol surface and the specificity of adsorption of the LUB molecules on the surface that still leads to low adsorption even at reduced layer densities (see FIG. 8 and elsewhere herein).

The results in FIG. 7a suggest that how the LUB molecule interacts and adsorbs to the surface influences its ability to prevent the non-specific adsorption of protein.

### Example 3—Effect of LUB Protein Density on Adsorption and Anti-Adhesive Properties

Another QCM experiment was devised in order to investigate how the density of the adsorbed LUB layer (i.e., the amount of LUB adsorbed to the surface) also affects its ability to prevent the non-specific adsorption of protein. FIG. 8 shows the relationship between the mass density of non-specifically adsorbed IgG as a function of the mass density of adsorbed LUB on an unmodified gold sensor surface. Also shown on FIG. 8 is the ‘% of saturated mass density’, which is the mass density of measured LUB layer normalized by the maximum mass density that was measured (i.e., the saturated mass density). While the lowest mass density of adsorbed IgG was achieved at 100% saturation, very little change was observed as the amount of adsorbed LUB was reduced to roughly 45% of saturation. Only after the mass density of the LUB layer was reduced further below 45% of saturation was a significant increase in the measured IgG binding density observed. These results indicate that the LUB layer, even well below its adsorbed saturation threshold, remains highly effective of blocking the adsorption of proteins.

### Example 4—Effect of Aging on LUB Protein Adsorption and its Anti-Adhesive Properties

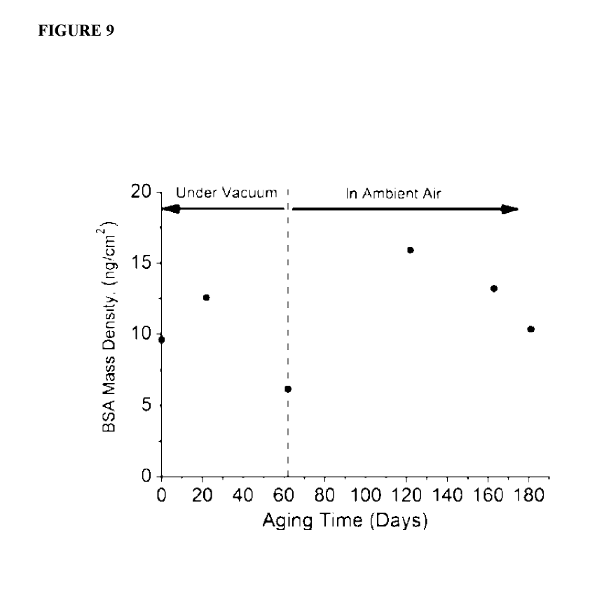

One of the desirable qualities of an anti-adhesive coating technology is durability and robustness that allows the coating to be applied to a surface and remain effective even after being stored over long periods of time under ambient conditions. Because LUB is a natural protein and since many natural proteins degrade when stored under non-ideal conditions, it was important to assess the stability of LUB anti-adhesive coatings over a long period of time under dry conditions and ambient temperatures. In this study, six gold QCM sensors were coated with a saturated mass of LUB protein and then stored first at room temperature under vacuum conditions for 62 days and then in ambient air for another 118 days (for a total of 180 days). At various times during this aging period, one of the QCM sensors was used to measure the amount of non-specifically adsorbed BSA protein (2 mg/ml in PBS at pH 7.4) on the aged LUB coated surface. As shown in FIG. 9, no significant change in the amount of non-specifically bound BSA was observed over the first 62 day period under vacuum storage conditions nor over the subsequent 118 day period under ambient air storage conditions. The anti-adhesive properties of the LUB coatings thus show excellent aging stability which should make them suitable for a wide range of anti-adhesive coating applications.

### Example 5—Effect of pH on the Anti-Adhesive Properties of LUB Protein

Four gold QCM sensor surfaces were coated with a saturated mass density of LUB protein and rinsed under a constant flow (150 μl/min) of PBS buffer at either pH 5.7, 6.5, 7.4, or 8.5 for 48 hours. After the 48 hour rinsing period, very little change in the QCM sensors frequencies were observed that would indicate a significant loss in the adsorbed mass from the LUB layers for all four buffer pH values. Although the QCM frequency shifted up and down due the fluctuations in the room temperature over this long period of time, the shifts (up and down) in all four QCM flow cells (at the different buffer pH values) were roughly the same (and always in the same direction). The rinsing of the LUB layers at all four pH values resulted in a loss in mass that was no more than ˜4% of the saturated mass value after 48 hours of continuous rinsing (and possibly less), demonstrating that LUB protein exhibits high stability and remains anchored to the surface for a long time.

### Example 6—Characterization of the Electrohydrodynamic Properties of Lubricin (LUB) Coatings

CE is a separation technique that takes advantage of differences in electrophoretic mobilities; that is, the differences in the ratio between the electrostatic charge and hydrodynamic radius of different analytes, which either speed up or slow down the migration rate of an analyte relative to a steady, electroosmotic-driven background fluid flow through a capillary. CE can be a powerful analytical technique; however, it is particularly sensitive to factors such as electrolyte concentration, pH, or the adsorption of analytes that have the potential to change or alters the electrostatic charge on the capillary walls. For this reason, proteins and other large, electrostatically charged molecules have been especially difficult to separate using CE due to their naturally high affinity for adsorbing to charged surfaces. For proteins, this is often true even if the surface and protein shares the same net charge.

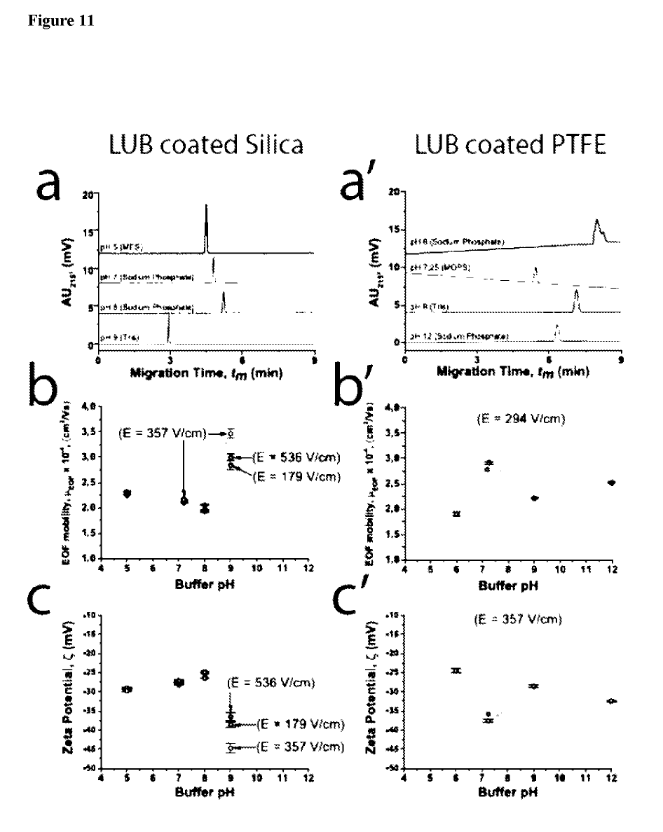

CE electrophoresis was used to measure the EOF velocity within LUB-coated silica and PTFE capillaries in order to assess the stability and consistency of the LUB coatings, how the electrostatic charging of the coatings are altered by changes in the run buffer pH, and how the electrohydrodynamic properties of the coatings are affected by the introduction of ‘sticky’ proteins into the capillary. FIGS. 11a and 11a′ show example CE data obtained for the migration times of acetone through a 28 cm long LUB-coated silica capillary (FIG. 11a) and a 34 cm long LUB-coated PTFE capillary (FIG. 11a′) under an applied electric field of 10 kV (E=357 V/cm and E=297 V/cm respectively) in various 15 mM background electrolyte buffers having a range of pH values.

The v_{EOF} was calculated from the measured migration times as described elsewhere herein. The (related) electroosmotic mobility, μ_{EOF}, and surface zeta potential, ζ, were both calculated from the experimentally measured v_{EOF} as described elsewhere herein. The relationship between the μ_{EOF} and run buffer pH is shown in FIGS. 11b and 11b′ for the LUB-coated silica and PTFE capillaries, respectively. The relationship between the ζ and run buffer pH is shown in FIGS. 11c and 11c′ for the LUB-coated silica and PTFE capillaries, respectively. For the silica capillaries, measurements were performed using three different electric field strengths: E=179, 357, and 536 V/cm (corresponding to voltages of V=5, 10, and 15 kV respectively) and were run in the order of lowest to highest E. For the PTFE capillary, measurements were conducted at only a single electric field strength of E=294 V/cm (V=10 kV). In the experiments shown in FIGS. 11b, 11b′, 11c and 11c′, the LUB coating was only applied once at the start of the experiment and the order in which the measurements were performed (i.e. the sequence of run buffer changes) is indicated by the red arrows in FIGS. 11b, 11b′, 11c and 11c′ In both capillaries, after completing the highest pH measurement at E=357 and 294 in the silica and PTFE capillaries, the pH was returned to neutral pH=7.2 and an additional measurement (shown as the green data point in FIGS. 11b and 11b′) was performed in order to ascertain the stability of the LUB coating. The values of μ_{EOF} obtained in the second and first measurements at pH=7.2 were essentially identical in both capillaries, indicating that no significant desorption or degradation of LUB coating occurred as a result of changing the run buffer pH.

In the LUB-coated silica (FIGS. 11b and 11c) and PTFE capillaries (FIGS. 11b′ and 11c′), the measured values of μ_{EOF} and ζ across the full range of pHs values were found to change very little and remained within a narrow range between μ_{EOF}=2.0-3.0×10⁻⁴ cm/Vs and ζ=−25-−40 mV. The similarity in the values of μ_{EOF} (and in the silica and PTFE capillaries suggests that the EOF is controlled primarily by the electrostatic charging within the LUB coating and, to a lesser extent by the underlying substrate. It is noted that the changes in μ_{EOF} observed as the run buffer pH value was changed appear exaggerated at the scale presented. Although small in magnitude, the observed changes in μ_{EOF} with increasing run buffer pH appear random and unpredictable, sometimes decreasing and sometimes increasing. However, the small variation in the values of μ_{EOF} measured at each pH (as indicated by the very small error bars) suggest that these changes may have been produced by very subtle variations in the electrostatic charging of the surface under these different buffer conditions.

However, the observed relationships between μ_{EOF} (and ζ) and pH in the silica and PTFE capillaries do not appear correlated and suggests that the adsorbed LUB layers in the two capillaries are also structurally different. As described elsewhere herein, the chemical properties of the substrate surface may affect the density of the self-assembled LUB brush layers. In this study, the density of the LUB brush absorbed onto a negatively charged thiol-SAM (similar, electrostatically, to silica) was approximately 15% higher than that absorbed to hydrophobic polystyrene (similar, electrostatically, to PTFE).

The conformational structure of the adsorbed LUB layer, being an essentially telechelic polyelectrolyte polymer brush, is dependent, at least in part, on the molecular grafting density and the magnitude of intermolecular (repulsive) electrostatic forces. For this reason, conformational changes caused by increased charging and stronger intra- and inter-chain repulsion in the LUB layer can lead to the mucin domain ‘loop’ becoming more extended. Since the zeta potential of the surface depends upon the density of the charge (i.e., the number of charges per unit volume rather than the absolute number of charges), it is possible that conformational changes (e.g. swelling) triggered by enhanced electrostatic repulsion can paradoxically lead to a reduction in the LUB layer charge density (as a result of the average distance between charges becoming greater) despite an increase in the absolute number of electrostatic charges in the layer.

As this happens, the paradoxical situation can arise in which the charge density within the LUB layer can decrease despite the number of charges in the layer increasing as a result of increasing the pH. Since the grafting density of LUB molecules on the surface of silica and PTFE are likely different, the effect of charging levels in the LUB is likely to lead to different conformational changes at different pHs and thus different changes in μ_{EOF} and ζ as the run buffer pH changes.

Second, since the LUB molecules self-assemble into what is essentially a polyelectrolyte brush layer, the thickness and structure of the brush layer will be effected by the strength of the electrostatic charging in the mucin domain. As the mucin domain becomes more charged, the strength of the intra-molecular and inter-molecular electrostatic forces in the layer increases and can lead to conformational changes; for example, the mucin domain becoming more extended. That leads to the molecule becoming more extended could lead to the charges in the molecule becoming farther apart, reducing the effective charge density in the layer despite the absolute number of negative charges becoming larger. Finally, given the difference observed in the changes in v_{EO} with pH between the LUB coated silica and PFTE capillaries, it is obvious that the underlying substrate has some influence upon the electroosmotic flow in the capillary; either by, itself, contributing to the total negative charge or through its interactions with the adsorbed LUB which previous studies have shown will adsorb to different surfaces in different densities.

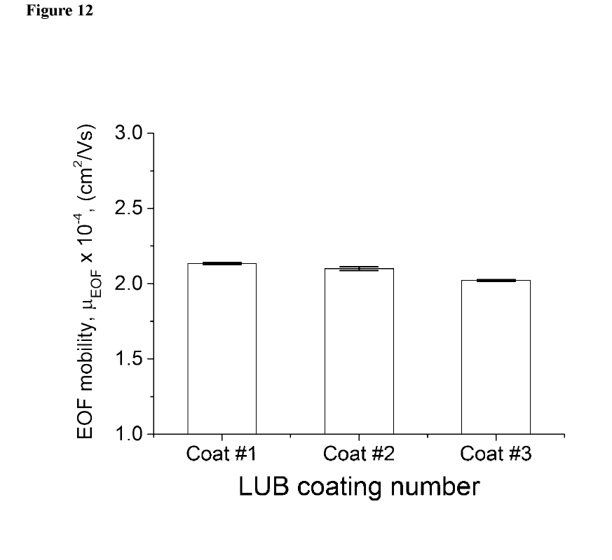

The migration times in a CE measurement are notoriously sensitive to subtle changes in the electroosmotic and electrophoretic flow velocity caused by even minor changes in the electrostatic charging of the capillary walls due to the adsorption of charged molecules. While FIG. 11 demonstrates that the electrohydrodynamic properties of the LUB coatings are highly stable in clean BGE, FIG. 12 demonstrates that properties of LUB coatings are consistent from coating to coating. An experiment was subsequently devised to investigate the stability of the electroosmotic flow when concentrated solutions of proteins are passed through the capillary. In this experiment, a mixed solution IgG and BSA proteins in a 10 mM MOPS buffer (pH 7.25) was hydrostatically injected into a LUB-coated PTFE capillary and electrohydrodynamically driven through the capillary under an applied potential of E=10 kV to study the effectiveness of the LUB coating for preventing the adsorption of proteins to the capillary walls and maintaining a steady, uniform, and repeatable EOF within the capillary.

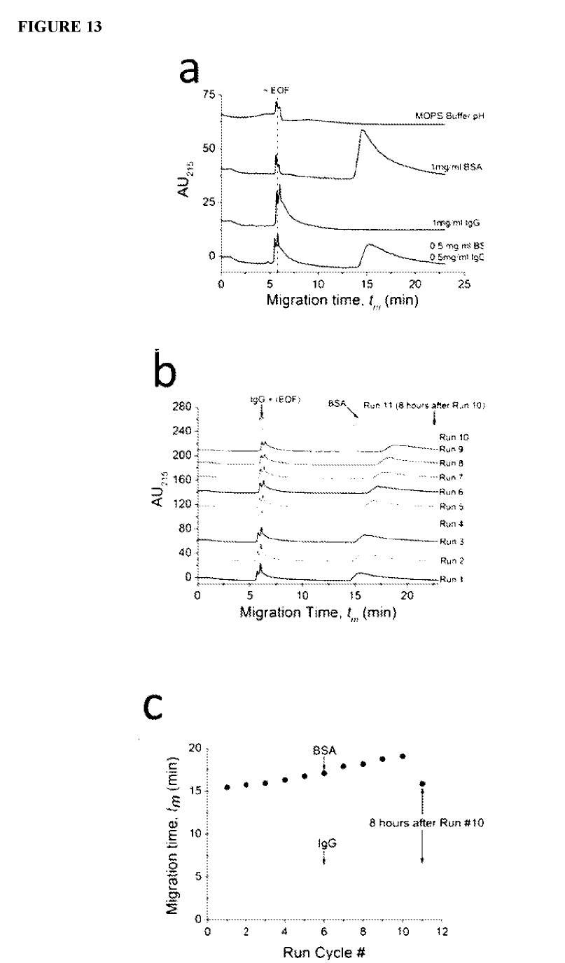

FIG. 13a shows the migration times obtained for the EOF of a clean BGE (pH 7.25; 10 mM MOPS) and single and mixed solutions of BSA and IgG. At pH 7.25, BSA is negatively charged and IgG is near its isoelectric point. Consequently, as expected, the IgG is observed eluting with the EOF peak while the BSA lags the EOF peak resulting in effective separation of the two proteins in the capillary. It is to be noted that the peak shapes obtained for both IgG and BSA in these measurements are broad and asymmetric, as opposed to narrow and symmetric that is typical of CE experiments. These measurements were intentionally performed under non-ideal conditions in which the capillary was overloaded with a higher than normal level of protein to amplify any changes in the EOF migration time caused by the adsorption of proteins to the capillary walls.

The effects of protein on the electrohydrodynamic properties of the LUB coatings was probed by performing a series of consecutively run separations of IgG and BSA (see FIGS. 13b and 13c). In this series of measurements, a drift to longer migration times with each consecutive separation was observed. Normally, a drift in the migration time of an analyte in CE indicates an instability in the EOF; that is, that there has been a change in the surface charge or surface charge density of the capillary surface. However, no appreciable change in the migration times for either the EOF or IgG peaks was observed over these series of measurements. In addition, it was noted that if the capillary was allowed to ‘rest’ for a period of time (in this case, overnight) and the measurement was repeated, the BSA peak was found to return to the original migration time measured in the very first measurement (i.e. run #1). Since no significant change in the EOF or IgG peak migration time was observed over the series of measurements, the observed drift in the BSA peak cannot be attributed to changes in the charging of the capillary wall that would have occurred if BSA was adsorbing to the LUB coating during the experiment.

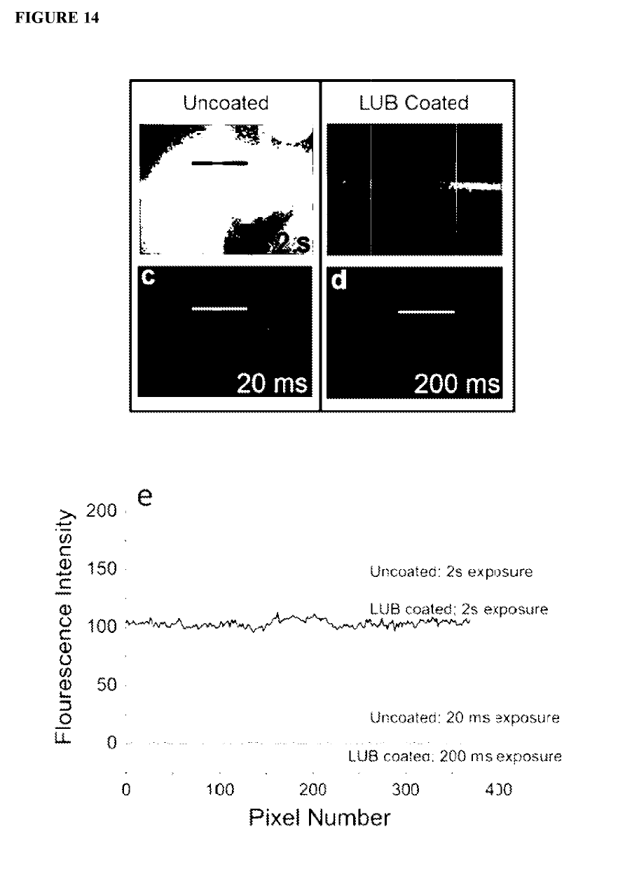

As noted elsewhere herein, one of the areas where multifunctional electrohydrodynamic and anti-adhesive LUB coatings have significant potential is in the area of microfluidics. Controlling the non-specific adsorption of proteins to the channel walls is challenging as well as vital to maintaining constant and uniform EOF in the device and high signal-to-noise ratios. To demonstrate the ability of LUB to reduce or eliminate non-specific binding of proteins in a microfluidic channel, a 2 mg/ml solution of fluorescently labelled IgG-FITC (10 mM MOPS; pH 7.25) was injected into an uncoated and a LUB-coated PDMS microfluidic cross-channel chip. After a period of 5 min, both uncoated and LUB-coated channels were flushed out with clean MOPS buffer and imaged using a fluorescence microscope (see FIGS. 14a-d). From these fluorescent micrographs, it was apparent that, at a 2s exposure time, the residual background fluorescence signal from non-specifically adsorbed IgG to the uncoated PDMS microchannel walls is substantial. A line scan of the fluorescence intensity across the channel indicated a very strong background fluorescence signal, as shown in FIG. 14e. At the same 2s exposure time, the background fluorescence of non-specifically adsorbed IgG observed in micrograph for the LUB coated microfluidic channel (FIG. 14b) was barely discernible. Indeed, the line trace of the fluorescence intensity for the LUB coated channel (at 2s exposure time) shown in FIG. 14e indicates that the residual fluorescence intensity due to non-specifically bound protein was barely greater than the level of background noise.

The 2s exposure times used to acquire the images in FIGS. 14a and 14b, however, resulted in overexposure and was far longer than the typical exposure times used to image the fluorescence in a device. A 20 ms exposure time is more typical and at this exposure time it is clear that the intensity of the residual background fluorescence due to non-specifically bound IgG in the uncoated PDMS channel was still significant (see FIG. 14c) and still results in a very strong background fluorescent ‘signal’ compared to the background fluorescent ‘noise’ in the line trace shown in FIG. 14e. In contrast, even at 200 ms (i.e. at a 10 times longer exposure time), no apparent background fluorescence was seen in the LUB-coated PDMS microfluidic channel (see FIG. 14d). The line trace obtained from this image shown in FIG. 14e indicates that the fluorescence intensity of the background fluorescence ‘signal’ was reduced to below the level of the background fluorescence ‘noise’.

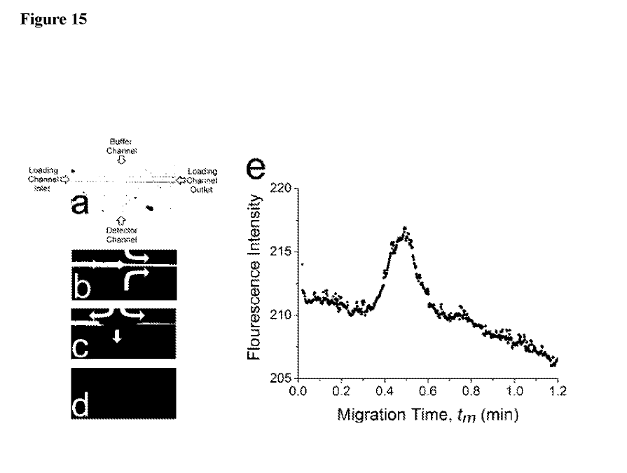

Lubricin coatings in microfluidic devices combine excellent anti-adhesive properties with a large and stable surface charge that makes it possible to drive the fluid flow ‘in-chip’ using electro-osmosis, even at relatively low applied voltages. FIG. 15 shows the electroosmotic injection (FIGS. 15a-d) and fluorescent detection (FIG. 15e) of a 0.5 mg/ml solution of IgG-FITC within a PDMS cross-channel chip. As described elsewhere herein, through appropriate manipulation of the electric field within the various channels, a steady flow of IgG from the loading channel inlet to the loading channel outlet was achieved and confined in the cross-channel region by convergent flows from the buffer and detector channels (FIG. 15b). Changing the electric field clears the IgG from the channels with flow from the buffer channel resulting in a plug of IgG migrating down the detector channel (FIG. 15c). Only a few seconds after the electric field change, within the region of the injection zone, all the IgG was removed from the channels with effectively zero residual background fluorescence (FIG. 15d). The plug of IgG sent down the detector channel, visible in FIG. 15c was observed by a detector located 2 cm away from the injection zone approximately 45 seconds after the injection. The change in the fluorescence intensity recorded as the plug of IgG passed by the detector is shown in FIG. 14e and resulted in a symmetric and reasonably sharp peak having a full width half maximum of 0.32 min. The images and data shown in FIG. 15 were taken from the fifth consecutive electrostatic injection performed on this particular chip, demonstrating that the low protein adhesion and background fluorescence is long lasting. In between different electrostatic injections of IgG, the microfluidic device was flushed out with clean buffer.

### CONCLUSIONS

The results of the studies disclosed herein demonstrate that LUB protein is a highly effective anti-adhesive agent with properties that are comparable to that of PEG. LUB was found to adsorb readily to a wide variety of substrates with different wetting, chemical, and electrostatic properties demonstrating that LUB coatings can be used as a facile method of rendering surfaces with desirable anti-adhesive properties; particularly hydrophobic and polymer surfaces on which it is often difficult to graft anti-adhesive polymers such as PEG (e.g., PS, PMMA). Though highly effective on many substrates, the LUB coatings were found to be most effective on hydrophobic, anionic, and polar (uncharged) surfaces. The enhanced anti-adhesive properties of the LUB coatings on these substrates can be attributed to LUB's ability to organize itself into a well ordered polymer brush-like layer, while the grafting density of the LUB molecules in this layer was found to be much less important. It was also found that the LUB coatings retained their ability to prevent the adhesion of proteins even at a low level of surface coverage far below saturation. The LUB coating also exhibited excellent long term stability and effectively zero loss of the anti-adhesive properties when stored at ambient temperatures under both vacuum and atmospheric conditions thus demonstrating the robustness of these coatings.

Furthermore, electrophoresis experiments demonstrated that EOF velocity of LUB-coated capillary surfaces, such as silica and PTFE, was very stable, even with changes in pH.

The ability of lubricin-coated surfaces to provide excellent long term stability and effectively zero loss of its anti-adhesive properties, combined with lubricin's relatively stable electrohydrodynamic properties, means that lubricin is a useful coating for microfluidic devices.

### REFERENCES

[1] Eteshola E, Leckband D. Development and characterization of an ELISA assay in PDMS microfluidic channels. Sens Actuat B-Chem 2001; 72:129e33.
[2] Arlett J L, Myers E B, Roukes M L. Comparative advantages of mechanical biosensors. Nat Nano 2011; 6:203e15.
[3] Lynch J F, Lappin-Scott H M, Costerton J W. Microbial biofilms. Cambridge, U K: Cambridge University Press; 2003. p. 86.
[4] Pop-Georgievski O, Popelka Stpn, Houska M, Chvostová D, Proks Vr, Rypacek Fe. Poly(ethylene oxide) layers grafted to dopamine-melanin anchoring layer: stability and resistance to protein adsorption. Biomacromolecules 2011; 12:3232e42.
[5] Alcantar N A, Aydil E S, Israelachvili J N. Polyethylene glycolecoated biocompatible surfaces. J Biomed Mat Res 2000; 51:343e51.
[6] Charles P, Stubbs V, Soto C, Martin B, White B, Taitt C. Reduction of nonspecific protein adsorption using poly(ethylene) glycol (PEG) modified polyacrylate hydrogels in immunoassays for staphylococcal enterotoxin B detection. Sensors 2009; 9:645e55.
[7] Humphries M, Nemcek J, Cantwell J B, Gerrard J J. The use of graft copolymers to inhibit the adhesion of bacteria to solid surfaces. FEMS Microbiol Lett 1987; 45:297e304.
[8] Kalman B, Castelino K, Chen F F, Majumdar A. Lithographic techniques and surface chemistries for the fabrication of PEG-passivated protein microarrays. Biosens Bioelectron 2006; 21:1960e7.
[9] Yue Z, Molino P J, Liu X, Wallace G G. PEGylation of platinum bio-electrodes. Electrochem Commun 2013; 27:54e8.
[10] VandeVondele S, V€or€os J, Hubbell J A. RGD-grafted poly-1-lysine-graft-(polyethylene glycol) copolymers block non-specific protein adsorption while promoting cell adhesion. Biotechnol Bioeng 2003; 82:784e90.
[11] George P A, Donose B C, Cooper-White J J. Self-assembling polystyrene-blockpoly (ethylene oxide) copolymer surface coatings: resistance to protein and cell adhesion. Biomaterials 2009; 30:2449e56.
[12] Reimhult K, Petersson K, Krozer A. QCM-D analysis of the performance of blocking agents on gold and polystyrene surfaces. Langmuir 2008; 24: 8695e700.
[13] Lee Y C. Biochemistry of carbohydrate-protein interaction. FASEB J 1992; 6: 3193e200.
[14] Makiguchi Y, Hinoda Y, Imai K. Effect of MUC1 mucin, an anti-adhesion molecule, on tumor cell growth. Cancer Sci 1996; 87:505e11.
[15] Sumiyoshi M, Ricciuto J, Tisdale A, Gipson I K, Mantelli F, Argueso P. Antiadhesive character of mucin 0-glycans at the apical surface of corneal epithelial cells. Invest Ophth Vis Sci 2008; 49:197e203.
[16] Chiquet-Ehrismann R. Inhibition of cell adhesion by anti-adhesive molecules. Curr Opin Cell Biol 1995; 7:715e9.
[17] Bavington C D, Lever R, Mulloy B, Grundy M M, Page C P, Richardson N V, et al. Anti-adhesive glycoproteins in echinoderm mucus secretions. Comp Biochem Physiol-B 2004; 139:607e17.
[18] Shi L, Ardehali R, Caldwell K D, Valint P. Mucin coating on polymeric material surfaces to suppress bacterial adhesion. Colloid Surf B 2000; 17:229e39.
[19] Bushnak I A, Labeed F H, Sear R P, Keddie J L. Adhesion of microorganisms to bovine submaxillary mucin coatings: effect of coating deposition conditions. Biofouling 2010; 26:387e97.
[20] Dedinaite A, Lundin M, Macakova L, Auletta T. Mucinechitosan complexes at the solid_liquid interface: multilayer formation and stability in surfactant solutions. Langmuir 2005; 21:9502e9.
[21] Das S, Banquy X, Zappone B, Greene G W, Jay G D, Israelachvili J N. Synergistic interactions between grafted hyaluronic acid and lubricin provide enhanced wear protection and lubrication. Biomacromolecules 2013; 14:1669e77.
[22] Jay G D. Lubricin and surfacing of articular joints. Curr Opin Orthop 2004; 15:355e9.
[23] Zappone B, Greene G W, Oroudjev E, Jay G D, Israelachvili J N. Molecular aspects of boundary lubrication by human lubricin: effect of disulfide bonds and enzymatic digestion. Langmuir 2008; 24:1495e508.
[24] Zappone B, Ruths M, Greene G W, Jay G D, Israelachvili J N. Adsorption, lubrication, and wear of lubricin on model surfaces: polymer brush-like behavior of a glycoprotein. Biophys J 2007; 92:1693e708.
[25] Aninwene G E I, Abadian P N, Ravi V, Taylor E N, Hall D, Mei A, et al. Lubricin: a novel means to decrease bacterial adhesion and proliferation. J Biomed Mater Res Part A 2014; 103:451e62.
[26] Rhee D K, Marcelino J, Baker M, Gong Y, Smits P, Lefebvre V, et al. The secreted glycoprotein lubricin protects cartilage surfaces and inhibits synovial cell overgrowth. J Clin Investigation 2005; 115(3): 622e31.
[27] Jay G, Harris D, Cha C-J. Boundary lubrication by lubricin is mediated by O-linked b(1-3)Gal-GalNAc oligosaccharides. Glycoconj J 2001; 18:807e15.
[28] Estrella R P, Whitelock J M, Packer N H, Karlsson N G. The glycosylation of human synovial lubricin: implications for its role in inflammation. Biochem J 2010; 429:359e67.
[29] Greene G W, Banquy X, Lee D W, Lowrey D D, Yu J, Israelachvili J N. Adaptive mechanically controlled lubrication mechanism found in articular joints. Proc Nat Acad Sci USA 2011; 108:5255e9.
[30] Greene G W, Zappone B, Banquy X, Lee D W, Soderman O, Topgaard D, et al. Hyaluronic acid-collagen network interactions during the dynamic compression and recovery of cartilage. Soft Matter 2012; 8:9906e14.
[31] Yu J, Banquy X, Greene G W, Lowrey D D, Israelachvili J N. The boundary lubrication of chemically grafted and cross-linked hyaluronic acid in phosphate buffered saline and lipid solutions measured by the surface forces apparatus. Langmuir 2011; 28:2244e50.
[32] Chang D P, Abu-Lail N I, Guilak F, Jay G D, Zauscher S. Conformational mechanics, adsorption, and normal force interactions of lubricin and hyaluronic acid on model surfaces. Langmuir 2008; 24:1183e93.
[33] Chang D P, Abu-Lail N I, Coles J M, Guilak F, Jay G D, Zauscher S. Friction force microscopy of lubricin and hyaluronic acid between hydrophobic and hydrophilic surfaces. Soft Matter 2009; 5:3438e45.
[34] Marx K A. Quartz crystal microbalance: a useful tool for studying thin polymer films and complex biomolecular systems at the solution_surface interface. Biomacromolecules 2003; 4: 1099e120.
[35] Jin J, Jiang W, Yin J, Ji X, Stagnaro P. Plasma proteins adsorption mechanism on polyethylene-grafted poly(ethylene glycol) surface by quartz crystal microbalance with dissipation. Langmuir 2013; 29:6624e33.
[36] Zhuang Y, Zhu Q, Tu C, Wang D, Wu J, Xia Y, et al. Protein resistant properties of polymers with different branched architecture on a gold surface. J Mater Chem 2012; 22:23852e60.
[37] Zhao H, Zhu B, Luo S-C, Lin H-A, Nakao A, Yamashita Y, et al. Controlled protein absorption and cell adhesion on polymer-brush-grafted poly(3,4-ethylenedioxythiophene) films. ACS Appl Mater Interfac 2013; 5:4536e43.
[38] Jay G D, Tones J R, Rhee D K, Helminen H J, Hytinnen M M, Cha C-J, et al. Association between friction and wear in diarthrodial joints lacking lubricin. Arthritis Rheumatism 2007; 56(11):3662e9.
[39] Greene G, Radhakrishna H, Tannenbaum R. Protein binding properties of surface-modified porous polyethylene membranes. Biomaterials 2005; 26:5972e82.
[40] Salloum D S, Schlenoff J B. Protein adsorption modalities on polyelectrolyte multilayers. Biomacromolecules 2004; 5:1089e96. [41] Silva R A, Urzua M D, Petri DFS, Dubin P L. Protein adsorption onto polyelectrolyte layers: effects of protein hydrophobicity and charge anisotropy. Langmuir 2010; 26:14032e8.
[42] Ostuni E, Chapman R G, Holmlin R E, Takayama S, Whitesides G M. A survey of structureeproperty relationships of surfaces that resist the adsorption of protein. Langmuir 2001; 17:5605e20.
[43] Dawson R M C, Elliot D C, Elliott W H, Jones K M. Data for biochemical research. 3rd ed. New York, N.Y.: Oxford University Press; 1989.
[44] Heuberger M, Drobek T, V€or€os J. About the role of water in surface-grafted poly(ethylene glycol) layers. Langmuir 2004; 20: 9445e8.
[45] Voinova M V, Rodahl M, Jonson M, Kasemo B. Viscoelastic acoustic response of layered polymer films at fluid-solid interfaces: continuum mechanics approach. Phys Scr 1999; 59:391.
[46] Voinova M V, Jonson M, Kasemo B. ‘Missing mass’ effect in biosensor's QCM applications. Biosens Bioelectron 2002; 17:835e41.
[47] Efremova N V, Huang Y, Peppas N A, Leckband D E. Direct measurement of interactions between tethered poly(ethylene glycol) chains and adsorbed mucin layers. Langmuir 2002; 18:836.

1. A microfluidic device comprising a substrate, wherein the substrate comprises a plurality of channels configured to transport a fluid, and wherein the plurality of channels are substantially coated with lubricin, or a functional variant thereof.

2. The device of claim 1, wherein the plurality of channels comprise a surface selected from the group consisting of a hydrophobic surface, an anionic surface, a polar surface and combinations thereof.

3. The device of claim 2, wherein the plurality of channels comprise a hydrophobic surface.

4. The device of claim 3, wherein the hydrophobic surface is a gold surface.

5. The device of claim 3, wherein the hydrophobic surface is a thiol-modified hydrophobic surface.

6. The device of claim 5, wherein the thiol is a OH-thiol or a CH₃-thiol.

7. The device of claim 1, wherein the plurality of channels comprise a COOH-thiol-modified surface.

8. The device of claim 1, wherein the plurality of channels comprise a polystyrene-modified surface.

9. The device of claim 1, wherein at least one of the plurality of channels is a capillary.

10. The device of claim 1, wherein at least one of the plurality of channels is a chromatography column.

11. The device of claim 1, wherein the plurality of channels are configured to form (i) at least one loading channel inlet, (ii) at least one loading channel outlet, (iii) at least one buffer channel and (iii) at least one detection channel, wherein the at least one loading channel inlet is in fluidic cooperation with the at least one loading channel outlet, which in turn is in fluidic cooperation with the buffer channel, which in turn is in fluidic cooperation with the detection channel.

12. The device of claim 11, wherein the device further comprises electrical contacts for coupling the device to an external power source.

13. The device of claim 12, wherein the device is capable of electrokinetic manipulation of fluid therein.

14. The device of claim 11, wherein the plurality of channels are configured to transport a biological fluid.

15. The device of claim 11, wherein the biological fluid is selected from the group consisting of blood, serum and plasma.

16. A method for manufacturing a microfluidic device comprising: (i) providing a substrate having a plurality of channels configured to transport a fluid, and (ii) applying to the plurality of channels a coating solution comprising lubricin, or a functional variant thereof, under conditions to allow the lubricin or functional variant thereof to substantially coat the plurality of channels.

17. The method of claim 16, wherein the substrate comprises (i) at least one loading channel inlet, (ii) at least one loading channel outlet, (iii) at least one buffer channel and (iii) at least one detection channel, wherein the at least one loading channel inlet is in fluidic cooperation with the at least one loading channel outlet, which in turn is in fluidic cooperation with the buffer channel, which in turn is in fluidic cooperation with the detection channel.

18. The method of claim 16, wherein the plurality of channels comprise a surface selected from the group consisting of a hydrophobic surface, an anionic surface, a polar surface and combinations thereof.

19. The method of claim 18, wherein the plurality of channels comprise a hydrophobic surface.

20. The method of claim 19, wherein the hydrophobic surface is a gold surface.

21. The method of claim 19, wherein the hydrophobic surface is a thiol-modified hydrophobic surface.

22. The method of claim 21, wherein the thiol is a OH-thiol or a CH₃-thiol.

23. The method of claim 16, wherein the plurality of channels comprise a COOH-thiol-modified surface.

24. The method of claim 16, wherein the plurality of channels comprise a polystyrene-modified surface.

25. A method of preventing fouling of a channel in a microfluidic device, the method comprising coating the channel with lubricin, or a functional variant thereof.

26. A method of controlling the electrokinetic flow of an analyte through a channel of a microfluidic device, the method comprising passing a fluid comprising the analyte through the channel under the influence of an electric field applied between a first position and a second position along the channel, wherein the channel is substantially coated with lubricin, or a functional variant thereof.

27. The method of claim 26, wherein the analyte is a protein or a nucleic acid molecule.

28. A chromatographic material for the electrophoretic or chromatographic separation of an analyte, wherein the chromatographic material is substantially coated with lubricin, or a functional variant thereof.

29. (canceled)

30. The chromatographic material of claim 28, wherein the analyte is a protein or a nucleic acid molecule.

31. The chromatographic material of claim 28, wherein the material is monolithic silica.

32. The device of claim 1, wherein the plurality of channels comprise a surface selected from the group consisting of silica, polystyrene, polymethylmethacrylate, polycarbonate, polydimethylsiloxane and combinations thereof.

33. The method of claim 16, wherein the plurality of channels comprise a surface selected from the group consisting of silica, polystyrene, polymethylmethacrylate, polycarbonate, polydimethylsiloxane and combinations thereof.

34. The method of claim 26, wherein the channel comprises a surface selected from the group consisting of silica, polystyrene, polymethylmethacrylate, polycarbonate, polydimethylsiloxane and combinations thereof.
